(19) United States
(12) Patent Application Publication
(10) Pub. No.: US 2010/0154711 A1
(43) Pub. Date: Jun. 24, 2010

(54) SUBSTRATE PROCESSING APPARATUS

(75) Inventors: Kiyohisa ISHIBASHI, Toyama-shi (JP); Fumihide IKEDA, Toyama-shi (JP); Masaaki UENO, Toyama-shi (JP); Takahiro MAEDA, Toyama-shi (JP); Yasuhiro INOKUCHI, Toyama-shi (JP); Yasuo KUNII, Takasaki-shi (JP); Hidehiro YANAGAWA, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/644,318

(22) Filed: Dec. 22, 2009

(30) Foreign Application Priority Data
Dec. 24, 2008 (JP) 2008-327708

(51) Int. Cl. C23C 16/00

(52) U.S. Cl. 118/725; 118/58

(57) ABSTRACT

Films are formed on a plurality of substrates through a batch process while preventing formation of films on the rear surfaces of the substrates. For this, a substrate processing apparatus comprises a reaction vessel, supports, a support holder, and an induction heating device. The reaction vessel is configured to process substrates therein. The supports are made of a conductive material and having a disk shape, and each of the supports is configured to accommodate a substrate in its concave part in a state where the substrate is horizontally positioned with a top surface of the substrate being exposed. The concave part is formed concentrically with a circumference of the support, and a difference between radii of the support and the concave part is greater than a distance between neighboring two of the supports held by the support holder. The support holder is configured to hold at least the supports horizontally in multiple stages. The induction heating device is configured to heat at least the supports held by the support holder inside the reaction vessel by using an induction heating method.

### CROSS-REFERENCE TO RELATED PATENT APPLICATION

This U.S. non-provisional patent application claims priority under 35 U.S.C. §119 of Japanese Patent Application No. 2008-327708, filed on Dec. 24, 2008, in the Japanese Patent Office, the entire contents of which are hereby incorporated by reference.

### BACKGROUND OF THE INVENTION

1. Field of the Invention

The present invention relates to a substrate processing apparatus.

2. Description of the Prior Art

In the conventional art, hot-wall type chemical vapor deposition (CVD) apparatuses are widely used as batch type substrate processing apparatuses. A reaction furnace is made of quartz, and a resistance heating method is used for heating the reaction furnace. When the reaction furnace is heated, the entire area of the reaction furnace is heated, and the temperature of the inside of the reaction furnace is controlled using a control unit. A source gas is supplied through a device such as a supply nozzle to form a film on a substrate.

(For example, refer to Patent Document 1) [Patent Document 1]

Japanese Unexamined Patent Application Publication No. 2008-277785

However, in the case where a film is formed on a substrate by using atypical film forming method and a conventional hot-wall type CVD apparatus, a film is formed on the rear surface of the substrate as well as the front surface of the substrate. Therefore, an additional process is necessary for removing the film from the rear surface of the substrate.

### SUMMARY OF THE INVENTION

An object of the present invention is to provide a substrate processing apparatus and a method of manufacturing a semiconductor device, which are designed to form desired films on the front surfaces of a plurality of substrates through a batch process while preventing formation of films on the rear surfaces of the substrates.

According to an aspect of the present invention, there is provided a substrate processing apparatus comprising: a reaction vessel configured to process substrates therein; supports made of a conductive material and having a disk shape, each of the supports being configured to accommodate a substrate in a concave part of the support in a state where the substrate is horizontally positioned with a top surface of the substrate being exposed; a support holder configured to hold at least the supports horizontally in multiple stages; and an induction heating device configured to heat at least the supports held by the support holder inside the reaction vessel by using an induction heating method, wherein the concave part is formed concentrically with a circumference of the support, and a difference between radii of the support and the concave part is greater than a distance between neighboring two of the supports held by the support holder.

According to another aspect of the present invention, there is provided a substrate processing apparatus comprising: a reaction vessel configured to process substrates therein; a first support made of a conductive material and comprising a first supporting part and a first plate on which the first supporting part is installed, the first supporting part being configured to support first and second substrates horizontally with rear surfaces of the first and second substrates being in contact with each other, the first plate being configured to form a first gap with the second substrate supported by the first supporting part; a second support made of a conductive material and disposed close to a top side of the first support; a support holder configured to hold the first support on a first support holding part and the second support on a second support holding part in a manner such that the first and second supports are horizontally positioned and arranged in multiple stages with a second gap being formed between the first and second supports; and an induction heating device configured to heat at least the first and second supports which are respectively held on the first and second support holding parts of the support holder inside the reaction vessel.

### BRIEF DESCRIPTION OF THE DRAWINGS

FIG. 1 is a schematic view illustrating a substrate processing apparatus according to a first embodiment of the present invention.

FIG. 2 is a schematic view illustrating a process furnace according to the first embodiment of the present invention.

FIG. 3 is a schematic horizontal sectional view illustrating the process furnace according to the first embodiment of the present invention.

FIG. 4 is a side sectional view illustrating a state where a wafer is accommodated in a concave part of a susceptor according to the first embodiment of the present invention.

FIG. 5 is a plan view illustrating the susceptor according to the first embodiment of the present invention.

FIG. 6 is a side sectional view illustrating a state where a wafer is pushed up from the susceptor by push pins according to the first embodiment of the present invention.

FIG. 7 is a side sectional view illustrating a state where a plurality of susceptors accommodating wafers in their concave parts are held on holding parts of a boat according to the first embodiment of the present invention.

FIG. 8 is a horizontal sectional view illustrating a state where a susceptor accommodating a wafer in its concave part is held on the holding parts of the boat according to the first embodiment of the present invention.

FIG. 9 is a side sectional view illustrating an example where the distance between susceptors is smaller than the width of peripheral parts of the susceptors according to the first embodiment of the present invention.

FIG. 10 is a side sectional view illustrating an example where heat conduction reducing materials are provided on the holding parts of the boat according to the first embodiment of the present invention.

FIG. 11 is a side sectional view illustrating an example where grooves are formed in posts of the boat as holding parts and heat conduction reducing materials are provided on the holding parts according to the first embodiment of the present invention.

FIG. 12 is a side sectional view illustrating an example where prismatic or cylindrical parts having a trapezoidal section with a top side shorter than a bottom side are provided at the holding parts of the boat according to the first embodiment of the present invention.

FIG. 13 is a side sectional view illustrating a state where dummy susceptors are provided at the upper side of a boat according to a second embodiment of the present invention.

FIG. 14 is a side sectional view illustrating a state where a plurality of susceptors accommodated wafers in their concave parts are held by the boat according to the first embodiment of the present invention.

FIG. 15 is a side sectional view illustrating an example where obtuse-angled parts are formed between the top and lateral peripheral surfaces of susceptors according to a third embodiment of the present invention.

FIG. 16 is a side sectional view illustrating an example where obtuse-angled parts are formed between the top and lateral peripheral surfaces and between the bottom and lateral peripheral surfaces of the susceptors according to the third embodiment of the present invention.

FIG. 17 is a side sectional view illustrating an example where the lateral peripheral surfaces of the susceptors are wholly rounded according to the third embodiment of the present invention.

FIG. 18 is a horizontal sectional view illustrating a process furnace according to a fourth embodiment of the present invention.

FIG. 19 is a horizontal sectional view illustrating a susceptor held at a boat according to a fifth embodiment of the present invention.

FIG. 20 is a side sectional view illustrating susceptors held at the boat according to the fifth embodiment of the present invention.

FIG. 21 is a side sectional view illustrating a state where the distance from the lower wafer of two wafers supported by a first susceptor held at the boat to the first susceptor is equal to the distance from the upper wafer of the two wafers to a neighboring second susceptor according to the fifth embodiment of the present invention.

FIG. 22 is a side sectional view illustrating an example where gas supply holes are provided to face first and second gaps, respectively, according to the fifth embodiment of the present invention.

FIG. 23 is a side sectional view illustrating an example where heat conduction reducing materials are provided at holding parts of the boat and supporting parts of the susceptors according to the fifth embodiment of the present invention.

FIG. 24 is a side sectional view illustrating an example where prismatic or cylindrical parts having a trapezoidal section with a top side shorter than a bottom side are provided at the holding parts of the boat, and prismatic or cylindrical parts having a trapezoidal section with a top side shorter than a bottom side are provided at the supporting parts of the susceptors according to the fifth embodiment of the present invention.

FIG. 25 is a side sectional view illustrating an example where obtuse-angled parts are formed between the top and lateral surfaces of the supporting parts of the susceptors according to the fifth embodiment of the present invention.

FIG. 26 is a side sectional view illustrating a state where the distance from the lower wafer of two wafers supported by a first susceptor held at a boat to the first susceptor is greater than the distance from a neighboring second susceptor to the upper wafer of the two wafers according to a sixth embodiment of the present invention.

FIG. 27 is a side sectional view illustrating an example where the size of a gas supply hole pointed to a second gap is greater that the size of a gas supply hole pointed to a first gap according to the sixth embodiment.

### DETAILED DESCRIPTION OF TILE PREFERRED EMBODIMENTS

Embodiments of the present invention will be described hereinafter with reference to the attached drawings.

### First Embodiment

In preferred embodiments of the present invention, a substrate processing apparatus is configured, for example, as a semiconductor manufacturing apparatus used to perform a processing process in a method of manufacturing a semiconductor device such as an integrate circuit (IC). In the following description, as a substrate processing apparatus, a vertical apparatus configured to perform a process such as an oxidation, diffusion, or chemical vapor deposition (CVD) process (hereinafter simply referred to as a processing apparatus) will be described.

Next, with reference to the attached drawings, a preferred embodiment of the present invention will be described in detail.

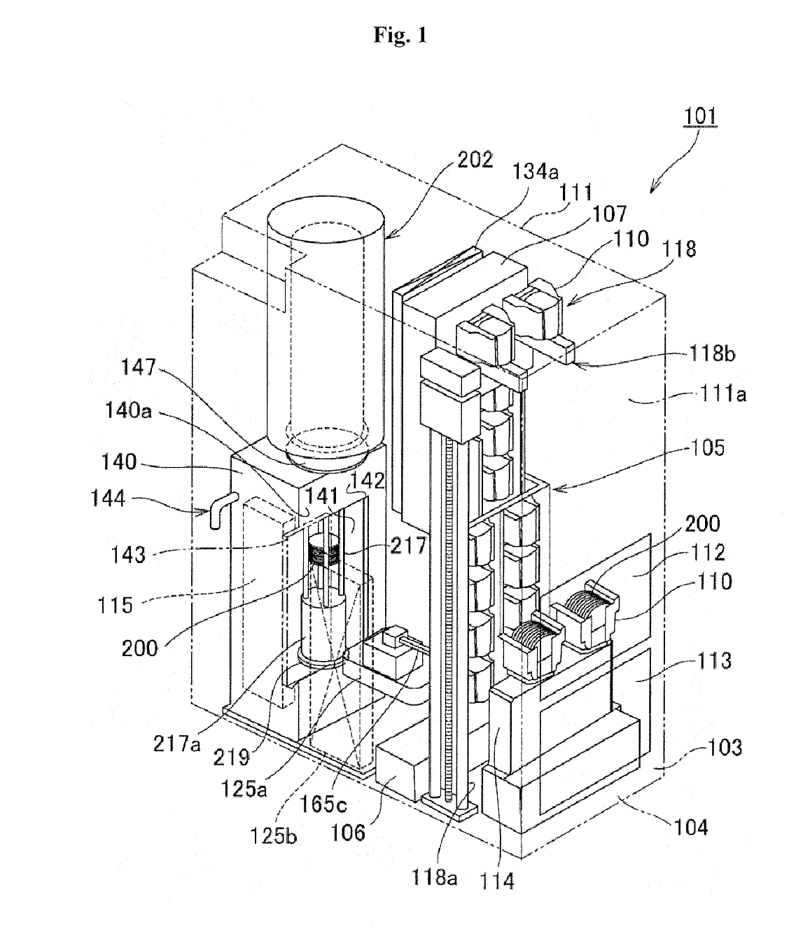

As shown in FIG. 1, a processing apparatus 101 of the present invention uses cassettes 110 as wafer carriers to accommodate wafers (substrates) 200 made of a material such as silicon, and the processing apparatus 101 includes a case 111. At the lower side of a front wall 111a of the case 111, a front maintenance port 103 is formed as an opening for maintenance works, and a front maintenance door 104 is installed for closing and opening the front maintenance port 103. At the front maintenance door 104, a cassette carrying port (substrate container carrying port) 112 is installed to connect the inside and outside of the case 111, and the cassette carrying port 112 is configured to be opened and closed by a front shutter (substrate container carrying port opening/closing mechanism) 113. At the inside of the cassette carrying port 112 of the case 111, a cassette stage (substrate container stage) 114 is installed. Cassettes 110 are configured to be carried onto the cassette stage 114 and carried away from the cassette stage 114 by an in-process carrying device (not shown). The cassette stage 114 is configured such that a cassette 110 can be placed on the cassette stage 114 by the in-process carrying device in a manner such that wafers 200 are vertically positioned in the cassette 110 and a wafer port of the cassette 110 faces upward.

Near the center lower part of the inside of the case 111 in a front-to-back direction, a cassette shelf (substrate container shelf) 105 is provided, and the cassette shelf 105 is configured to store a plurality of cassettes 110 in multiple rows and columns in a manner such that wafers 200 can be carried into and out of the cassettes 110. The cassette shelf 105 is installed in a manner such that the cassette shelf 105 can be horizontal moved on a slide stage (horizontal movement mechanism) 106. In addition, a buffer shelf (substrate container storage shelf) 107 is installed at the upper side of the cassette shelf 105 to store cassettes 110.

Between the cassette stage 114 and the cassette shelf 105, a cassette carrying device (substrate container carrying device) 118 is installed. The cassette carrying device 118 includes a cassette elevator (substrate container elevating mechanism) 118a capable of holding and moving cassettes 110 vertically, and a cassette carrying mechanism (substrate container carrying mechanism) 118b as a carrying mechanism, so that cassettes 110 can be carried among the cassette stage 114, the cassette shelf 105, and the buffer shelf 107 by consecutive operations of the cassette elevator 118a and the cassette carrying mechanism 118b.

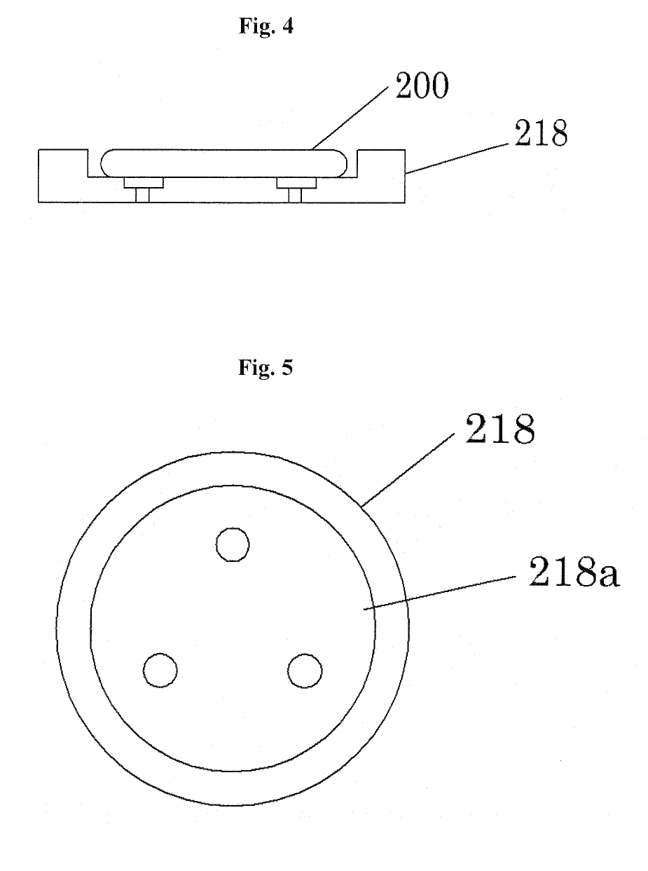

At the rear side of the cassette shelf 105, a wafer transfer mechanism (substrate transfer mechanism) 125 is provided. The wafer transfer mechanism 125 includes a wafer transfer device (substrate transfer device) 125a capable of rotating or linearly moving a wafer 200 on a horizontal plane, and a wafer transfer device elevator (substrate transfer device elevator) 125b configured to raise and lower the wafer transfer device 125a. As schematically shown in FIG. 1, the wafer transfer device elevator 125b is provided at the left end part of the case 111. By consecutively operating the wafer transfer device elevator 125b and the wafer transfer device 125a and using tweezers (substrate holding part) 125c of the wafer transfer device 125a as a wafer placement part, a wafer 200 can be charged onto and discharged from a susceptor 218 (refer to FIG. 4) disposed on a susceptor holding mechanism (not shown).

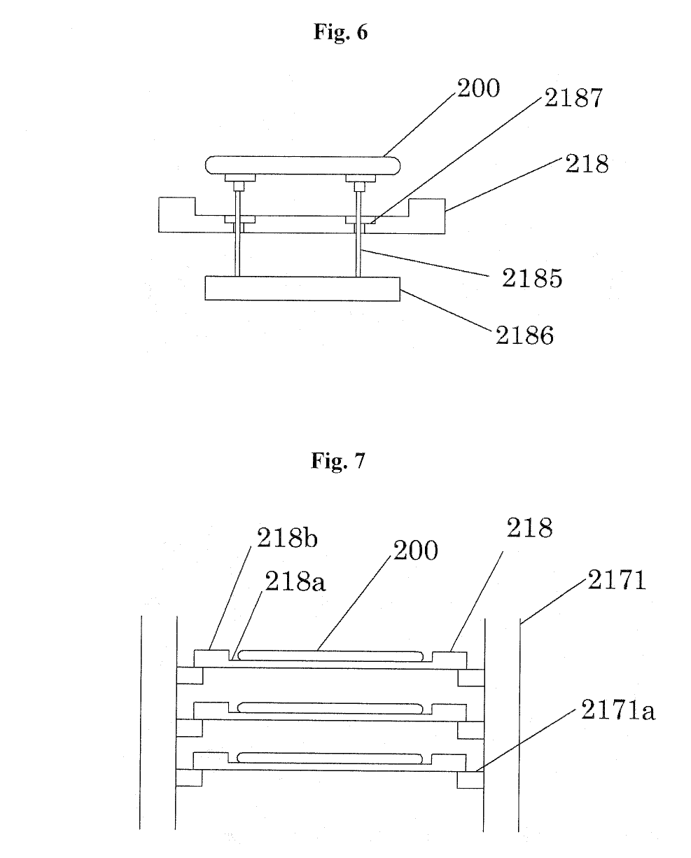

Three pin holes 2187 (refer to FIG. 6) are formed in the susceptor 218. As shown in FIG. 4 to FIG. 6, the susceptor holding mechanism includes three push pins 2185 inserted in the pin holes 2187.

The push pins 2185 configured to push a wafer 200 and a push pin elevating mechanism 2186 are provided for charging and discharging of a wafer 200 between the tweezers 125c and the susceptor 218. In addition, it is preferable that the leading ends of the push pins 2185 have a flange shape so as to prevent a wafer 200 from being damaged when pushed by the push pins 2185 and reduce heat radiation through the pin holes 2187.

A susceptor moving mechanism (not shown) is configured to charge and discharge the susceptor 218 between the susceptor holding mechanism and a boat (substrate holder) 217.

As shown in FIG. 1, at the rear side of the buffer shelf 107, a cleaning unit 134a configured by a supply fan and a dust filter is provided to supply clean air as a cleaned atmosphere, so that clean air can be circulated in the case 111.

In addition, at the right-end part opposite to the wafer transfer device elevator 125b, another cleaning unit configured by a supply fan and a filter is installed to supply clean air, and air blown by the cleaning unit flows through the wafer transfer device 125a and is sucked by an exhaust unit (not shown), where the air is exhausted to the outside of the case 111.

At the rear side of the wafer transfer device (substrate transfer device) 125a, a case 140 (hereinafter, referred to as a pressure-resistant case) is installed, which is airtight and can be kept at a pressure (hereinafter, referred to as a negative pressure) lower than atmospheric pressure. The pressure-resistant case 140 forms a loadlock chamber 141 which is a loadlock type standby chamber having a sufficient volume for accommodating the boat 217.

At a front wall 140a of the pressure-resistant case 140, a wafer carrying port (substrate carrying port) 142 is formed, which is configured to be opened and closed by a gate valve (substrate carrying port opening/closing mechanism) 143. A gas supply pipe 144 configured to supply inert gas such as nitrogen gas to the loadlock chamber 141 and an exhaust pipe (not shown) configured to exhaust the loadlock chamber 141 to a negative pressure are respectively connected to a pair of sidewalls of the pressure-resistant case 140.

At the upper side of the loadlock chamber 141, a process furnace 202 is provided. The bottom side of the process furnace 202 is configured to be opened and closed by a furnace port gate valve (furnace port opening/closing mechanism) 147.

As schematically shown in FIG. 1, in the loadlock chamber 141, a boat elevator (support holder elevating mechanism) 115 is installed to raise and lower the boat 217. At an arm (not shown) connected to the boat elevator 115 as a connecting tool, a seal cap 219 is horizontal installed as a cover, and the seal cap 219 is configured to support the boat 217 vertically and close the bottom side of the process furnace 202.

The boat 217, which is a support holder, is provided with a plurality of holding members and is configured to hold a plurality of susceptors 218 (for example, fifty to one hundred of susceptors 218) horizontally in a state where the susceptors 218 are vertically arranged with their centers being aligned.

Next, an operation of the processing apparatus 101 will be described according to a preferred embodiment of the present invention.

As shown in FIG. 1, before a cassette 110 is supplied to the cassette stage 114, the cassette carrying port 112 is opened by moving the front shutter 113. Thereafter, a cassette 110 is carried through the cassette carrying port 112 and placed on the cassette stage 114 in a manner such that wafers 200 accommodated in the cassette 110 are vertically positioned and the wafer port of the cassette 110 faces upward.

Next, by the cassette carrying device 118, the cassette 110 is picked up from the cassette stage 114 and is vertically rotated by 90° counterclockwise to the rear side of the case 111, so that the wafers 200 accommodated in the cassette 110 can be horizontal positioned and the wafer port of the cassette 110 can face the rear side of the case 111. Subsequently, the cassette 110 is automatically carried to and placed on a designated shelf position of the buffer shelf 107 by the cassette carrying device 118, and after the cassette 110 is temporarily stored, the cassette 110 is transferred to the cassette shelf 105 by the cassette carrying device 118; or the cassette 110 is directly carried to the cassette shelf 105 by the cassette carrying device 118.

The slide stage 106 moves the cassette shelf 105 horizontally so as to place a cassette 110 to be transferred at a position facing the wafer transfer device 125a.

A wafer 200 is picked up from the cassette 110 through the wafer port of the cassette 110 by the tweezers 125c of the wafer transfer device 125a. At the susceptor holding mechanism, the push pins 2185 are moved upward by the push pin elevating mechanism 2186. Subsequently, the wafer 200 is placed on the push pins 2185 by the wafer transfer device 125a.

Subsequently, the push pin elevating mechanism 2186 lowers the push pins 2185 where the wafer 200 is placed, so as to place the wafer 200 on the susceptor 218.

When the wafer carrying port 142 of the loadlock chamber 141 which is previously kept at atmospheric pressure is opened by operating the gate valve 143, the susceptor moving mechanism discharges the susceptor 218 from the susceptor holding mechanism and carries the susceptor 218 into the loadlock chamber 141 through the wafer carrying port 142 so as to charge the susceptor 218 into the boat 217.

The wafer transfer device 125a returns to the cassette 110 and charges the next wafer 200 to the susceptor holding mechanism. The susceptor moving mechanism returns to the susceptor holding mechanism so as to charge the boat 217 with a susceptor 218 where the next wafer 200 is placed.

If a predetermined number of susceptors 218 is charged to the boat 217, the wafer carrying port 142 is closed by the gate valve 143, and the loadlock chamber 141 is decompressed by vacuuming through the exhaust pipe. If the pressure of the loadlock chamber 141 becomes equal to the inside pressure of the process furnace 202, the bottom side of the process furnace 202 is opened by moving the furnace port gate valve 147. Next, the seal cap 219 is moved upward by the boat elevator 115 so as to load the boat 217 supported on the seal cap 219 into the process furnace 202 (loading).

After the loading of the boat 217, a predetermined processing process is performed on the wafers 200 in the process furnace 202. After the processing process, the boat 217 is taken out by the boat elevator 115, the inside pressure of the loadlock chamber 141 is adjusted back to atmospheric pressure, and then the gate valve 143 is opened. Thereafter, the wafers 200 and the cassette 110 are discharged to the outside of the case 111.

Next, the process furnace 202 of the processing apparatus 101 will be described according to a preferred embodiment of the present invention.

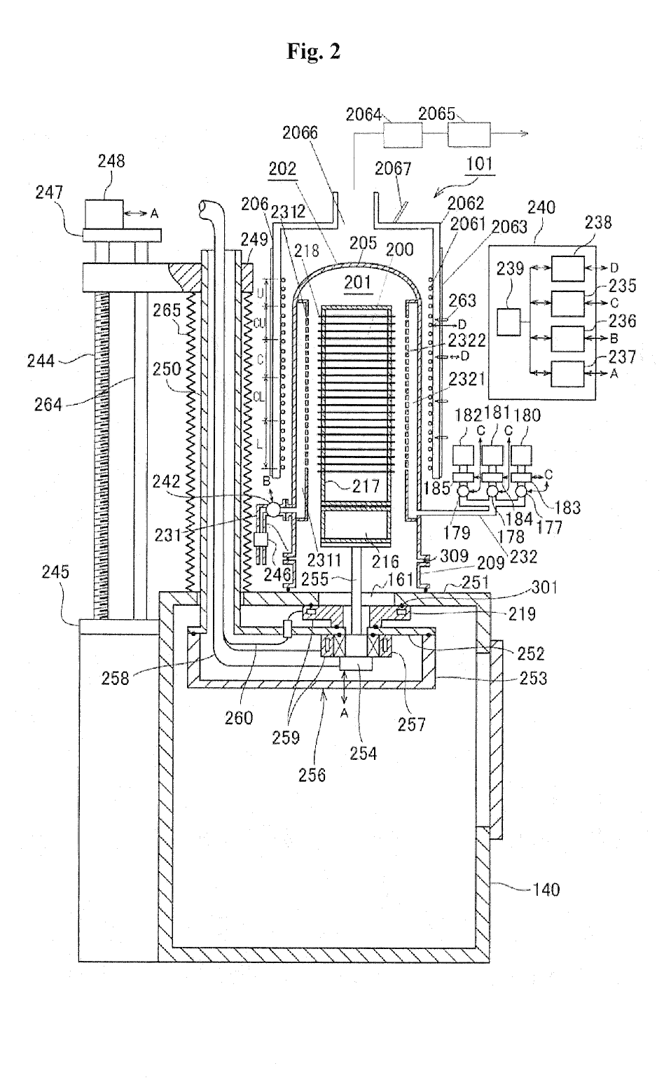

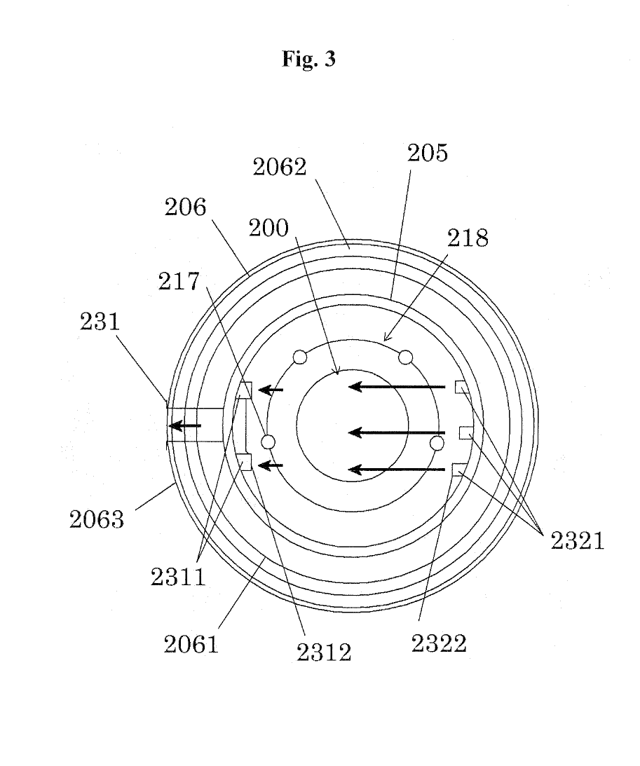

FIG. 2 is a schematic vertical sectional view schematically illustrating the process furnace 202 of the processing apparatus 101 and the periphery of the process furnace 202 according to a preferred embodiment of the present invention. In addition, FIG. 3 is a schematic horizontal sectional view illustrating the process furnace 202 of the processing apparatus 101 according to a preferred embodiment of the present invention.

As shown in FIG. 2 and FIG. 3, the process furnace 202 includes an induction heating device 206 to which a high-frequency electric current can be applied.

The induction heating device 206 has a cylindrical shape and is configured by a radio frequency (RF) coil 2061 functioning as an induction heating unit, a wall part 2062, and a cooling wall 2063. The RF coil 2061 is connected to a high-frequency power source (not shown).

The wall part 2062 is made of a metal such as stainless steel and has a cylindrical shape. At the inner side of the wall part 2062, the RF coil 2061 is provided. The RF coil 2061 is supported by a coil supporting part (not shown). The coil supporting part is supported by the wall part 2062 with a predetermined gap in a radial direction between the RF coil 2061 and the wall part 2062.

At the outer side of the wall part 2062, the cooling wall 2063 is provided coaxially with the wall part 2062. At the center of the top side of the wall part 2062, an opening part 2066 is provided. A duct is connected to the downstream side of the opening part 2066, and a radiator 2064 functioning as a cooling device and a blower 2065 functioning as an exhaust device are connected to the downstream side of the duct.

A cooling medium passage is formed through almost the entire region of the cooling wall 2063 so as to make a flow of a cooling medium such as a coolant through the cooling wall 2063. A cooling medium supply unit (not shown) and a cooling medium discharge unit (not shown) are connected to the cooling wall 2063 to supply a cooling medium and discharge the cooling medium. By supplying a cooling medium from the cooling medium supply unit and discharging the cooling medium to the cooling medium discharge unit, the cooling wall 2063 can be cooled, and thus the wall part 2062 and the inside of the wall part 2062 can be cooled by thermal conduction.

At the inner side of the RF coil 2061, an outer tube 205 is provided coaxially with the induction heating device 206 as a reaction tube constituting a reaction vessel. The outer tube 205 is made of a heat-resistant material such as quartz (SiO₂) and has a cylindrical shape with a closed top side and an opened bottom side. Inside the outer tube 205, a process chamber 201 is formed. In the process chamber 201, substrates such as wafers 200 can be accommodated in a state where the wafers 200 are horizontally positioned and vertically arranged in multiple stages by using the boat 217 and susceptors 218 made of a conductive material.

At the lower side of the outer tube 205, a manifold 209 is installed coaxially with the outer tube 205. For example, the manifold 209 is made of a material such as quartz (SiO₂) and stainless steel and has a cylindrical shape with opened top and bottom sides. The manifold 209 is provided to support the outer tube 205. Between the manifold 209 and the outer tube 205, an O-ring 309 is provided as a seal member. The manifold 209 is supported by a holding body (not shown) in a manner such that the outer tube 205 can be vertical fixed. The outer tube 205 and the manifold 209 constitute a reaction vessel.

In addition, the manifold 209 is not limited to the case where the manifold 209 and the outer tube 205 are separately provided. That is, instead of providing the manifold 209 separately, the manifold 209 and the outer tube 205 may be provided in one piece.

At the lateral inner wall of the outer tube 205, a gas supply chamber 2321 made of quartz (SiO₂) is provided so as to supply gas to the wafers 200 disposed in the process chamber 201 in a direction toward lateral sides of the wafers 200, and a gas exhaust chamber 2311 made of quartz (SiO₂) is provided so as to exhaust gas passing through the wafers 200 in the process chamber 201 in a direction away from the other lateral sides of the wafers 200.

The gas supply chamber 2321 is provided at the lateral inner wall of the outer tube 205 by welding, the top side of the gas supply chamber 2321 is closed, and a plurality of gas supply holes 2322 are formed in the sidewall of the gas supply chamber 2321.

The gas exhaust chamber 2311 is provided at the lateral inner wall of the outer tube 205 by welding, the top side of the gas exhaust chamber 2311 is closed, and a plurality of gas discharge holes 2312 are formed in the sidewall of the gas exhaust chamber 2311.

Preferably, gas supply chambers 2321 may be provided at a plurality of positions so as to supply gas to the respective wafers 200 placed in the boat 217 uniformly. More preferably, gas supply directions from gas supply holes 2322 of the plurality of gas supply chambers 2321 may be parallel.

In addition, it is preferably that the plurality of gas supply chambers 2321 be symmetric with respect to a center line of the wafers 200.

Preferably, gas exhaust chambers 2311 may be provided at a plurality of positions so as to uniformly exhaust gas passing through the respective wafers 200 placed in the boat 217. More preferably, it may be configured that gas exhaust directions through gas discharge holes 2312 of the plurality of gas exhaust chambers 2311 are parallel. In addition, it is preferable that the plurality of the gas exhaust chambers 2311 be symmetric with respect to the center line of the wafers 200.

Preferably, so as to supply gas to the plurality of wafers 200 placed in the boat 217 uniformly, the gas supply holes 2322 may be provided at predetermined heights from the top surfaces of the wafers 200, respectively, so that the gas supply holes 2322 can face gaps formed above the wafers 200, respective.

Preferably, so as to discharge gas passing through the plurality of wafers 200 placed in the boat 217 uniformly, the gas discharge holes 2312 may be provided at predetermined heights from the top surfaces of the wafers 200, respectively, so that the gas discharge holes 2312 can face gaps formed above the wafers 200, respectively.

Preferably, so as to enable gas to flow the center parts of the wafers 200 easily, the gas supply holes 2322 and the gas discharge holes 2312 may be provided at opposing positions with the boat 217 being disposed therebetween.

At the lower outer sidewall of the outer tube 205, a gas exhaust pipe 231 communicating with the gas exhaust chambers 2311 is provided, and a gas supply pipe 232 communicating with the gas supply chambers 2321 is provided.

Alternatively, the gas exhaust pipe 231 may be provided, for example, at the sidewall of the manifold 209 instead of at the lower outer sidewall of the outer tube 205. In addition, the gas supply pipe 232 may communicate with the gas supply chambers 2321, for example, at the sidewall of the manifold 209 instead of at the lower sidewall of the outer tube 205.

The upstream side of the gas supply pipe 232 is divided into three parts which are respectively connected to a first gas supply source 180, a second gas supply source 181, and a third gas supply source 182 through values 177, 178, and 179 and gas flowrate control devices such as mass flow controllers (MFCs) 183, 184, and 185. A gas flowrate control unit 235 is electrically connected to the MFCs 183, 184, and 185 and the values 177, 178, and 179, so that a desired amount of gas can be supplied at a desired time.

A vacuum exhaust device 246 such as a vacuum pump is connected to the downstream side of the gas exhaust pipe 231 through a pressure detector (not shown) such as a pressure sensor and a pressure regulator such as an automatic pressure control (APC) value 242.

A pressure control unit 236 is electrically connected to the pressure sensor and the APC valve 242, and the pressure control unit 236 controls the opened area of the APC valve 242 based on a pressure detected by the pressure sensor so that the inside pressure of the process chamber 201 can be adjusted to a desired pressure at a desired time.

At the bottom side of the manifold 209, the seal cap 219 is provided as a furnace cover for hermetically closing the opened bottom side of the manifold 209. For example, the seal cap 219 may be formed of a metal such as stainless steel and has a disk shape. On the top surface of the seal cap 219, an O-ring 301 is provided as a seal member making contact with the bottom side of the manifold 209.

At the seal cap 219, a rotary mechanism 254 is provided.

A rotation shaft 255 of the rotary mechanism 254 is connected to the boat 217 through the seal cap 219 so as to rotate the wafers 200 by rotating the boat 217.

The seal cap 219 is configured to be moved upward and downward by an elevating motor 248 (described later) which is provided at an outer side of the process furnace 202 as an elevating mechanism, so that the boat 217 can be loaded into and unloaded from the process chamber 201.

A driving control unit 237 is electrically connected to the rotary mechanism 254 and the elevating motor 248 so as to control the rotary mechanism 254 and the elevating motor 248 for performing desired operations at desired times.

At the induction heating device 206, the RF coil 2061 having a spiral shape is provided in a state where the RF coil 2061 is vertically divided into a plurality of regions (zones). For example, as shown in FIG. 2, the RF coil 2061 is divided into five zones from the lower side: an RF coil 2061L, an RF coil 2061CL, an RF coil 2061C, an RF coil 2061CU, and an RF coil 2061U. The respective RF coils 2061 can be independently controlled.

Near the induction heating device 206, radiation thermometers 263 are provided at four positions as temperature detectors for detecting inside temperatures of the process chamber 201. The number of the radiation thermometers 263 may be one; however, preferably, the number of the radiation thermometers 263 may be two or more for improving temperature controllability.

A temperature control unit 238 is electrically connected to the induction heating device 206 and the radiation thermometers 263 to control power supplied to the induction heating device 206 based on temperature information detected by the radiation thermometers 263, so that desired temperature distribution can be obtained inside the process chamber 201 at a desired time.

The temperature control unit 238 is electrically connected to the blower 2065. The temperature control unit 238 is configured to control the blower 2065 according to a preset manipulation recipe. As the blower 2065 operates, atmosphere existing between the wall part 2062 and the outer tube 205 is discharged through the opening part 2066. After being discharged through the opening part 2066, the atmosphere is cooled by the radiator 2064 and discharged to equipment (not shown) located at the downstream side of the blower 2065. That is, by operating the blower 2065, the induction heating device 206 and the outer tube 205 can be cooled.

The cooling medium supply unit and the cooling medium discharge unit connected to the cooling wall 2063 are configured to be controlled by a controller 240, so that a desired amount of cooling medium can flow through the cooling wall 2063 at a desired time for obtaining a desired cooling condition. The use of the cooling wall 2063 is preferable because heat radiation to the outside of the process furnace 202 can be easily suppressed and the outer tube 205 can be cooled more easily owing to the cooling wall 2063; however, if a desired cooling condition can be obtained by only using the blower 2065, the cooling wall 2063 may be not used.

At the top side of the wall part 2062, an explosion relief hole is formed separately from the opening part 2066, and an explosion relief hole opening/closing device 2067 is provided to close and open the explosion relief hole.

When hydrogen gas and oxygen gas are mixed and ignited inside the wall part 2062, since an additional pressure is added to the wall part 2062, weak parts such as bolts, screws, and a panel installed at the wall part 2062 may be broken and blown to increase damage of the wall part 2062.

To minimize such damage, when pressure increases to a predetermined level due to an explosion, the explosion relief hole opening/closing device 2067 is released to open the explosion relief hole for relieving the increased pressure.

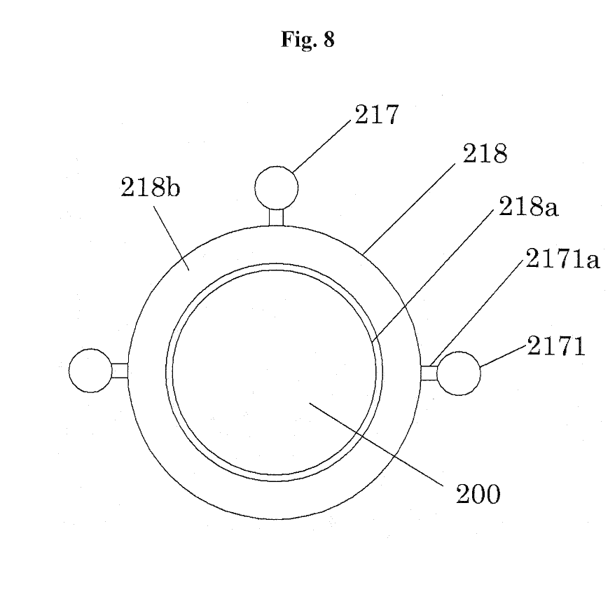

The boat 217, which is a support holder, is provided with a disk-shaped bottom plate, a disk-shaped top plate, and three or four posts made of quartz to connect the bottom and top plates. Referring to FIGS. 7 and 8, holding parts 2171a extend from each of posts 2171 toward the center axis of the boat 217 so as to support susceptors 218 which are substrate supports.

As shown in FIGS. 7 and 8, each of the susceptors 218 which are supports is shaped like a disk having a diameter larger than that of a wafer 200, and a concave part 218a is formed on a main surface of the disk. The diameter of the concave part 218a is slightly greater than that of the wafer 200. The concave part 218a is formed in a manner such that the concave part 218a makes contact with at least the peripheral part of the rear surface of the wafer 200. Since wafers 200 are accommodated in the concave parts 218a of the susceptors 218, when the susceptors 218 are held by the boat 217 in multiple stages, the distance between the vertically neighboring susceptors 218 can be reduced.

Particularly, due to thermal effects by a low-temperature region between the outer tube 205 and the boat 217, the temperature of gaps between the vertically neighboring susceptors 218 decreases as it goes away form the susceptors 218. However, since it is configured that wafers 200 are accommodated in the concave parts 218a of the susceptors 218, the distance between the vertically neighboring susceptors 218 can be reduced, and thus gas flowing between the vertically neighboring susceptors 218 can be heated uniformly and efficiently to improve the uniformity of the thickness and quality of films formed on the wafers 200.

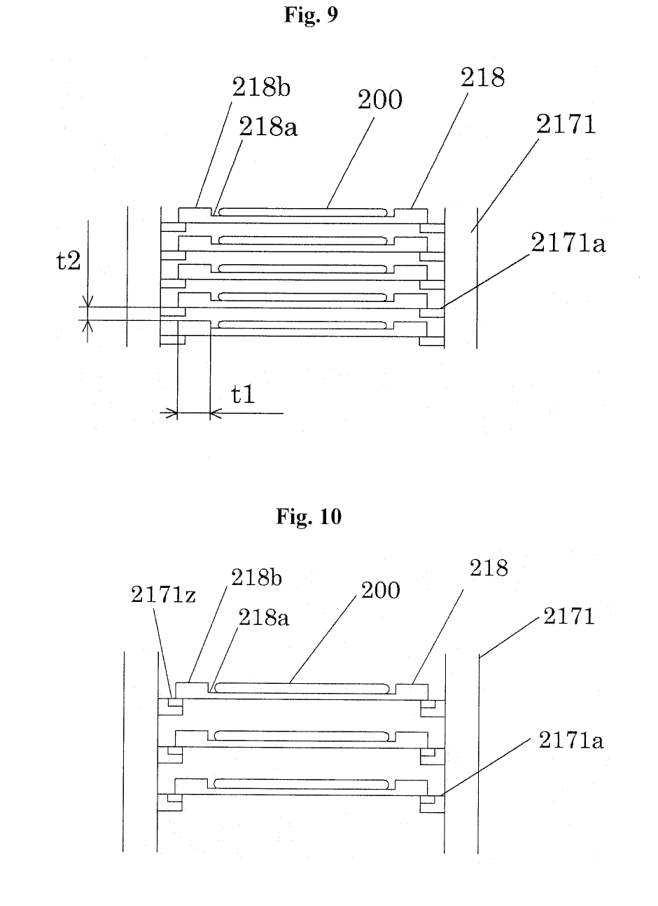

Preferably, as shown in FIG. 9, the susceptors 218 are formed in a disk shape, the concave parts 218a are formed concentrically with the susceptors 218, and the difference t1 between the radius of peripheral parts 218b of the susceptors 218 and the radius of the concave parts 218a is greater than the distance t2 between the vertically neighboring susceptors 218 held at the boat 217. In this case, substantially, gas flowing between the susceptors 218 can be heated more uniformly and efficiently, and thus the thickness uniformity of films formed on wafers 200 can be improved without having to an unnecessary gas discharging operation. In addition, when the boat 217 and the susceptors 218 are rotated to supply gas to the wafers 200 uniformly, thermal radiation from the vertically neighboring susceptors 218 held by the boat 217 is significant. Therefore, it is particularly effective that: the susceptors 218 are formed in a disk shape, the concave parts 218a are formed concentrically with the susceptors 218, and the difference between the radius of the peripheral parts 218b of the susceptors 218 and the radius of the concave parts 218a is greater than the distance between the vertically neighboring susceptors 218 held at the boat 217.

More preferably, the susceptors 218 may be formed in a disk shape, the concave parts 218a may be formed concentrically with the susceptors 218, and the difference between the radius of the peripheral parts 218b of the susceptors 218 and the radius of the concave parts 218a may be two times to ten times greater than the distance between the vertically neighboring susceptors 218 held at the boat 217. In this case, gas flowing between the susceptors 218 can be heated more uniformly and efficiently, and thus the thickness uniformity of films formed on wafers 200 can be improved without having to perform an unnecessary gas discharging operation.

Much more preferably, the susceptors 218 may be formed in a disk shape, the concave parts 218a may be formed concentrically with the susceptors 218, and the difference between the radius of the peripheral parts 218b of the susceptors 218 and the radius of the concave parts 218a may be three times to five times greater than the distance between the vertically neighboring susceptors 218 held at the boat 217. In this case, since gas flowing between the susceptors 218 can be heated much more uniformly and efficiently, although the posts 2171 of the boat 217 hinder the gas flow between the susceptors 218, the amount of gas supplied to the wafers 200 is not undesirably affected over the entire areas of the wafers 200, and the thickness and quality uniformities of films formed on the wafers 200 can be improved without having to perform an unnecessary gas discharging operation.

If it is configured that the difference between the radius of the peripheral parts 218b of the susceptors 218 and the radius of the concave parts 218a is ten times or more greater than the distance between the vertically neighboring susceptors 218 held at the boat 217, the size of the process furnace 202 becomes excessively large, and thus a dead space may increase. Furthermore, since gas is consumed at the peripheral parts 218b of the susceptors 218, wafers 200 may be inefficiently processed.

In addition, it is preferable that the depth of the concave parts 218a be equal to the thickness of wafers 200. That is, the depth of the concave parts 218a is adjusted such that when wafers 200 are placed, the peripheral parts 218b of the susceptors 218 can be horizontally coplanar with the top surfaces of the wafers 200, respectively. In this case, gas introduced through lateral sides of the susceptors 218 can flow smoothly along the peripheral parts 218b to the top surfaces of the wafers 200 without generating turbulent flows and deposits. In addition, if the wafers 200 are processed at a high temperature, the positions of the wafers 200 can be varied due to, for example, thermal deformation. However, since the wafers 200 are accommodated in the concave parts 218a, such position variation can be suppressed. Furthermore, the concave parts 218a make contact with at least the peripheral parts of the rear surfaces of the wafers 200, and the peripheral parts 218b of the susceptors 218 are horizontally coplanar with the top surfaces of the wafers 200. Therefore gas is difficult to reach the rear surfaces of the wafers 200, and thus depositions of films on the rear surfaces of the wafers 200 can be suppressed. It is preferable that the susceptors 218 have a disk shape so as to heat the wafers 200 uniformly in the circumferential direction; however, although the susceptors 218 have a plat shape having elliptical or polygonal principal surface, it is allowable in the current embodiment.

The susceptors 218 are held by the holding parts 2171a of the posts 2171, such that the susceptors 218 can be horizontally positioned.

The susceptors 218 are provided separately from the posts 2171 so as to be attached to and detached from the posts 2171. The susceptors 218 are made of a conductive material (such as carbon or carbon graphite) coated with silicon carbide (SiC).

At the lower part of the boat 217, an insulating cylinder 216 is disposed as a cylindrical insulating member made of a heat-resistant material such as quartz (SiO₂), so that heat transfer from the induction heating device 206 to the manifold 209 can be difficult. Instead of providing the insulating cylinder 216 as a separate part from the boat 217, the insulating cylinder 216 and the boat 217 can be formed in one piece. Furthermore, instead of the insulating cylinder 216, a plurality of insulating plates can be provided at the lower part of the boat 217.

The boat 217 will now be described again in more detail.

When a film forming process is performed on wafers 200 inside the process chamber 201, it is preferable that the boat 217 do not release high-concentration contaminants, so as prevent permeation of contaminants into the films.

In addition, if the boat 217 is made of a material having a high thermal conductivity, the quartz insulating cylinder 216 disposed at the lower part of the boat 217 can be degraded by heat. Thus, it is preferable that the boat 217 be made of a material having a low thermal conductivity. Furthermore, since it is preferable that the boat 217 have no thermal influence on wafers 200 placed on the susceptors 218, preferably, the boat 217 is made of a material that is not induction-heated by the induction heating device 206. When these requirements are considered, the boat 217 may be made of quartz. However, in the case where the boat 217 is made of only quartz, if a process is performed on wafers 200 while keeping the susceptors 218 at 1000° C. to 1200° C., the boat 217, particularly, the holding parts 2171a can be thermally degraded due to heat directly transferred from the susceptors 218. Therefore, if the boat 217 is made of quartz, it is preferable that heat conduction reducing materials 2171z having a low thermal conductivity be disposed on the holding parts 2171a as shown in FIG. 10. For example, the heat conduction reducing materials 2171z may be sintered silicon nitride. It is preferable that at least contact surfaces with the susceptors 218 be provide with heat conduction reducing materials.

If permeation of contaminants into films is not significant when a film forming process is performed on wafers 200, preferably, alumina (Al₂O₃) may be used for the boat 217 as heat conduction reducing materials having a thermal conductivity lower that that of the susceptors 218. The thermal conductivity of alumina is higher than quartz but much lower than silicon carbide (SiC). In addition, alumina is not readily degraded by heat and not induction-heated.

In addition, if thermal degradation of the quartz insulating cylinder 216 can be negligible, preferably, the boat 217 may be made of a heat conduction reducing material such as silicon carbide (SiC) having a thermal conductivity lower than that of the susceptors 218, and so as not to be induction-heated, the boat 217 may be made of a material having a resistance higher than that of the susceptors 218 that can be induction-heated. For example, when the resistance of the susceptors 218 that can be induction-heated is in the range from 0.1 Ωcm to 0.15 Ωcm, it is preferable that the boat 217 be made of a material having a resistance equal to or higher 2 Ωcm.

Furthermore, since the holding parts 2171a extend from the respective posts 2171 toward the center axis of the boat 217, the posts 2171 can be spaced apart from the susceptors 218. Therefore, the susceptors 218 can be less thermally affected by the posts 2171, and a flow of gas can be less hindered by the posts 2171 so that the thickness of films formed on wafers 200 can be less undesirably affected.

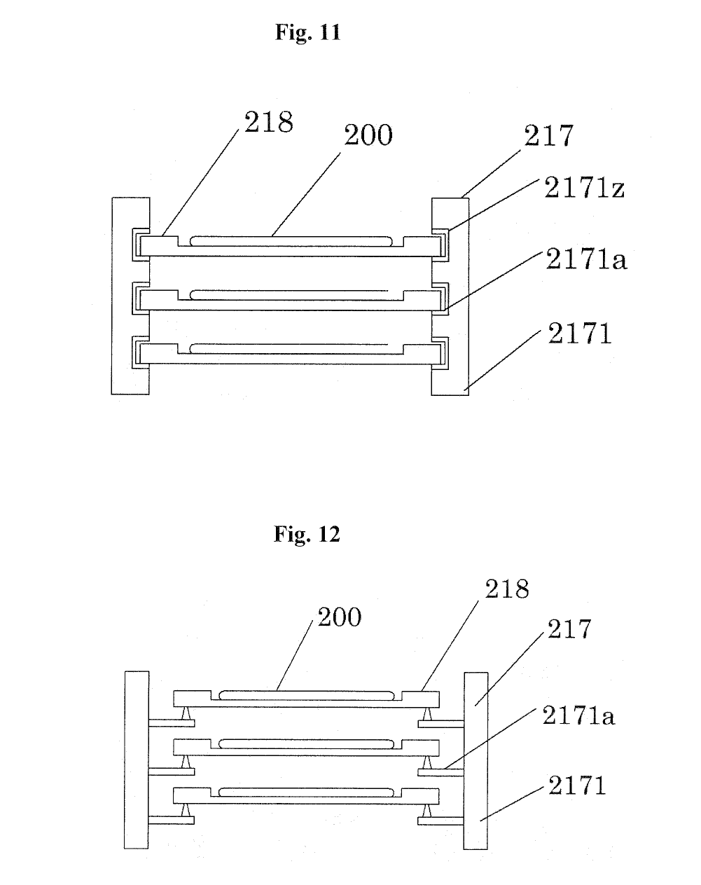

However, the holding parts 2171a are not limited to the structure where the holding parts 2171a extend from the posts 2171. For example, as shown in FIG. 11, the holding parts 2171a can be provided in the form of grooves formed in the posts 2171. If the boat 217 made of quartz is used in this case, when the susceptors 218 are accommodated in the grooves, the susceptors 218 are disposed close to sidewalls and bottom walls of the grooves as well as the contact surfaces with the grooves. Therefore, it is preferable that the heat conduction reducing materials be provided on the side and bottom walls of the grooves as well as contact surfaces with the susceptors 218.

In addition, as shown in FIG. 12, it is preferable that prismatic or cylindrical parts having a trapezoidal section with a top side shorter than a bottom side be provided at the holding parts 2171a, so as to reduce the contact areas with the susceptors 218 while maintaining strength. In this case, direct heart transfer from the susceptors 218 to the holding parts 2171a can be suppressed, and thus deformation and breakage of the holding parts 2171a can be prevented. In this case, if the boat 217 is made of a material that is thermally degraded at temperatures lower than a wafer processing temperature, it is preferable that heat conduction reducing materials be provided on at least contact surfaces with the susceptors 218 as described above.

The boat 217 is configured such that each set of holding parts 2171a holds one susceptor 218 and each susceptor 218 accommodates one wafer 200, and in this way, fifty to one hundred susceptors 218 and the same number of wafers 200 can be charged into the boat 217.

In the structure of the process furnace 202, a first process gas is supplied from the first gas supply source 180, and after the flowrate of the first process gas is controlled at the MFC 183, the first process gas is introduced into the process chamber 201 through the valve 177, the gas supply pipe 232, the gas supply chamber 2321, and the gas supply holes 2322. A second process gas is supplied from the second gas supply source 181, and after the flowrate of the second process gas is controlled at the MFC 184, the second process gas is introduced into the process chamber 201 through the valve 178, the gas supply pipe 232, the gas supply chamber 2321, and the gas supply holes 2322. A third process gas is supplied from the third gas supply source 182, and after the flowrate of the third process gas is controlled at the MFC 185, the third process gas is introduced into the process chamber 201 through the valve 179, the gas supply pipe 232, the gas supply chamber 2321, and the gas supply holes 2322. Gas introduced into the process chamber 201 is exhausted through the gas discharge holes 2312, the gas exhaust chamber 2311, the gas exhaust pipe 231, and the vacuum exhaust device 246.

Next, the peripheral structure of the processing apparatus 101 will be described according to the present invention.

At the outside of the pressure-resistant case 140, which forms the loadlock chamber 141 as a standby chamber, a lower base 245 is provided. A guide shaft 264 fitted to an elevating stage 249 and a ball screw 244 screw-coupled with the elevating stage 249 are provided at the lower base 245. At the upper ends of the guide shaft 264 and the ball screw 244 erected on the lower base 245, an upper base 247 is provided. The ball screw 244 is rotated by the elevating motor 248 provided at the upper base 247. As the ball screw 244 is rotated, the elevating stage 249 is moved upward and downward.

At the elevating stage 249, a hollow elevating shaft 250 is installed to be extended from the elevating stage 249, and a connection part between the elevating stage 249 and the elevating shaft 250 is hermetically sealed. The elevating shaft 250 is configured to be moved upward and downward together with the elevating stage 249. The elevating shaft 250 is movably inserted through a top plate 251 of the loadlock chamber 141. A penetration hole of the top plate 251 through which the elevating shaft 250 is movably inserted is sufficiently large so that the elevating shaft 250 does not make contact with the wall of the penetration hole. Between the loadlock chamber 141 and the elevating stage 249, a bellows 265 is installed around the elevating shaft 250 as a flexible hollow part for keeping the loadlock chamber 141 hermetically. The bellows 265 is sufficiently flexible so that the bellows 265 can be deformed according to upward and downward movements of the elevating stage 249, and the inner diameter of the bellows 265 is sufficiently larger than the outer diameter of the elevating shaft 250 so that the elevating shaft 250 does not make contact with the bellows 265 while the bellows 265 is extended and contracted.

An elevating base 252 is horizontally fixed to the lower end of the elevating shaft 250. A driving unit cover 253 is hermitically attached to the bottom side of the elevating base 252 with a seal member such as an O-ring being disposed therebetween. The elevating base 252 and the driving unit cover 253 constitute a driving unit accommodation case 256. Owing to this structure, the inside of the driving unit accommodation case 256 can be isolated from the inside atmosphere of the loadlock chamber 141.

In addition, at the inside of the driving unit accommodation case 256, the rotary mechanism 254 of the boat 217 is installed, and the periphery of the rotary mechanism 254 is cooled by a cooling mechanism 257.

A power supply cable 258 extends from the upper end of the elevating shaft 250 to the rotary mechanism 254 through the hollow part of the elevating shaft 250, and then the power supply cable 258 is connected to the rotary mechanism 254. In addition, at the cooling mechanism 257 and the seal cap 219, cooling passages 259 are formed, and coolant pipes 260 are connected to the cooling passages 259 for supplying coolant. The coolant pipes 260 extend from the upper end of the elevating shaft 250 through the hollow part of the elevating shaft 250.

As the ball screw 244 is rotated by operating the elevating motor 248, the driving unit accommodation case 256 is moved upward and downward through the elevating base 249 and the elevating shaft 250.

As the driving unit accommodation case 256 is moved upward, a furnace port (opening) 161 of the process furnace 202 is closed by the seal cap 219 which is hermetically provided at the elevating base 252, so that a wafer processing condition can be obtained. As the driving unit accommodation case 256 is moved downward, the seal cap 219 and the boat 217 are lowered, and in this state, wafers 200 can be carried to the outside.

The gas flowrate control unit 235, the pressure control unit 236, the driving control unit 237, and the temperature control unit 238 constitute a manipulation unit and an input/output unit, and they are electrically connected to a main control unit 239. The gas flowrate control unit 235, the pressure control unit 236, the driving control unit 237, the temperature control unit 238, and the main control unit 239 are configured as the controller 240.

Next, as an example of substrate manufacturing processes performed by using the above-described process furnace 202, a method of forming a semiconductor film such as a silicon (Si) film on a substrate such as a wafer 200 by using CVD reaction will now be described.

In the following description, operations of the respective parts of the processing apparatus 101 are controlled by the controller 240.

After a plurality of susceptors 218 on which wafers 200 are placed are charged into the boat 217, as shown in FIG. 2, the boat 217 charged with the susceptors 218 is loaded into the process chamber 201 by the lifting operations of the elevating base 249 and the elevating shaft 250 actuated by the elevating motor 248 (boat loading). In this state, the bottom side of the manifold 209 is sealed by the seal cap 219 with the O-ring 301 being disposed therebetween.

The inside of the process chamber 201 is evacuated by the vacuum exhaust device 246 to a desired pressure. At this time, the inside pressure of the process chamber 201 is measured by using the pressure sensor, and the pressure regulator 242 is feedback-controlled based on the measured pressure. For example, the desired pressure may be a pressure selected from the range of about 13300 Pa to about 0.1 MPa.

The blower 2065 is operated to create flows of gas or air between the induction heating device 206 and the outer tube 205 for cooling the sidewall of the outer tube 205, the gas supply chamber 2321, the gas supply holes 2322, the gas exhaust chamber 2311, and the gas discharge holes 2312. As a cooling medium, a coolant is circulated through the radiator 2064 and the cooling wall 2063 so as to cool the inside of the induction heating device 206 through the wall part 2062.

In addition, so as to keep the wafers 200 at a desired temperature, high-frequency power is applied to the induction heating device 206 to induce currents in the susceptors 218.

At this time, to obtain desired temperature distribution at the inside of the process chamber 201, power applied to the induction heating device 206 is feedback-controlled based on temperature information detected by using the radiation thermometers 263. In addition, at this time, the blower 2065 is controlled according to preset control variables so as to cool the sidewall of the outer tube 205, the gas supply chamber 2321, the gas supply holes 2322, the gas exhaust chamber 2311, and the gas discharge holes 2312 to a temperature, for example, 600° C. or lower, which is much lower than a film glowing temperature of the wafers 200. The wafers 200 are heated, for example, to a 1100° C. The wafers 200 are heated to a constant temperature selected from process temperatures ranging from 700° C. to 1200° C., and in any cases, the sidewall of the outer tube 205, the gas supply chamber 2321, the gas supply holes 2322, the gas exhaust chamber 2311, and the gas discharge holes 2312 are cooled to a temperature, for example, 600° C. or lower, which is much lower than a film forming temperature of the wafers 200, by controlling the blower 2065 according to preset control variables.

Subsequently, the boat 217 is rotated by the rotary mechanism 254 so as to rotate the susceptors 218 and the wafers 200 placed on the susceptors 218.

In the first gas supply source 180, the second gas supply source 181, and the third gas supply source 182, a silicon containing gas such as trichlorosilane (SiIICl₃), a boron containing gas such as diborane (B₂H₆), and hydrogen (H₂) gas are filled as a process gas, a dopant gas, and a carrier gas, respectively. When the temperature of the wafers 200 is stabilized, process gases are supplied from the first gas supply source 180, the second gas supply source 181, and the third gas supply source 182. After the opened areas of the MFCs 183, 184, and 185 are controlled for obtaining desired flowrates, the valves 177, 178, and 179 are opened to introduce the process gases into the gas supply chamber 2321 through the gas supply pipe 232. Since the flow-passage section of the gas supply chamber 2321 is sufficiently greater than the size of the gas supply holes 2322, the pressure of the gas supply chamber 2321 becomes greater than the pressure of the process chamber 201, and thus the gases can be injected into the process chamber 201 through the gas supply holes 2322 at a uniform flowrate and flow velocity. The gases supplied to the process chamber 201 are allowed to flow through the process chamber 201 and are then discharged to the gas exhaust chamber 2311 through the gas discharge holes 2312, and thereafter, the gases are exhausted through the gas exhaust pipe 231. When the process gases flow between the susceptors 218, the process gases are heated by the upper and lower neighboring susceptors 218, and at the same time, the process gases make contact with the wafers 200, so that semiconductor films such as Si films can be formed on the surfaces of the wafers 200 by CVD reaction.

After a preset time, inert gas is supplied from an inert gas supply source (not shown) so as to replace the inside gas atmosphere of the process chamber 201 with the inert gas, and at this time, the inside pressure of the process chamber 201 returns to atmospheric pressure.

Thereafter, the seal cap 219 is moved downward by the elevating motor 248 so as to open the bottom side of the manifold 209 and unload the boat 217 in which the processed wafers 200 are held to the outside of the outer tube 205 through the bottom side of the manifold 209 (boat unloading). After that, the processed wafers 200 are discharged from the boat 217 (wafer discharging).

According to the current embodiment, one or more of the following effects can be attained.

(a) Since a film can be formed on a wafer 200 in a state where the wafer 200 is accommodated in the concave part 218a of a susceptor 218, the uniformity of in-surface film thickness can be improved, and at the same time, growth of a film on the rear surface of the wafer 200 can be suppressed because film-forming gas is difficult to reach the rear side of the wafer 200. Therefore, for example, it may be unnecessary to perform a process of removing a substance attached to the rear surface.

(b) Since films can be grown on wafers 200 in a state where susceptors 218 accommodating the wafers 200 in their concave parts 218a are held by the boat 217, the distance (pitch) between the susceptors 218 held by the boat 217 can be reduced. Therefore, the number of susceptors 218 can be increased to increase the number of wafers 200 that can be processed at one time while improving the uniformities of film thickness and film quality (inter-surface film thickness uniformity and inter-surface film quality uniformity) between wafers 200 processed together at one time.

(c) Susceptors 218 accommodating wafers 200 in their concave parts 218a are arranged at the holding parts 2171a of the boat 217 in multiple stages so as to reduce the gap between the susceptors 218, and thus two susceptors 218 adjacent to a gap can be uniformly heated for heating gas flowing through the gap. Therefore, the uniformities of in-surface film thickness and in-surface film quality can be efficiently improved.

(d) Since susceptors 218 are provided separately from the boat 217 and are configured to be attached to and detached from the boat 217, it is easy to change the number of the susceptors 218, and it is possible to change the pitch width between the susceptors 218 for changing the pitch width between wafers 200 so that process window can be widened.

(e) Since wafers 200 can be heated while controlling the temperature of the outer tube 205 not to increase, desired films can be grown on the wafers 200 while suppressing growth and deposition of films on the inner wall of the outer tube 205. Particularly, when thick films having a thickness of several micrometers or higher are formed on the wafers 200, the wafers 200 may have to be processed at a temperature of 700° C. to 1200° C. to obtain a necessary film growth rate of 0.01 μm/min to 2 μm/min. In this case, since the outer tube 205 can be kept at a relatively low temperature, growth and deposition of films on the inner wall of the outer tube 205 can be suppressed so that maintenance works such as self cleaning and wet cleaning can be less frequently performed. Furthermore, when the accumulated thickness of a film increases excessively, the stress of the film increases to cause breakage of a quartz member; however, according to the current embodiment, this phenomenon can be suppressed.

(f) When the outer tube 205 is used as a vacuum-proof vessel, although the upper temperature limit of the outer tube 205 is about 950° C. for safety reason, wafers 200 are processed at a high temperature of 1200° C. in the outer tube 205; however, breakage of the outer tube 205 and resulting gas leakage can be prevented because the temperature of the outer tube 205 can be kept at 600° C. or lower.

(g) Since the temperature of the gas supply chamber 2321 and the gas supply holes 2322 can be controlled to not increase, gas consumption at the gas supply chamber 2321 can be reduced, and since clogging of the gas supply chamber 2321 and the gas supply holes 2322 can be prevented, process gas can be sufficiently supplied to wafers 200.

(h) In the case of using a boron-containing gas such as diborane (B₂H₆) gas, boron trichloride (BCl₃) gas, and boron trifluoride (BF₃) as a dopant gas, since the decomposition and reaction of B₂H₆, BCl₃, and BF₃ are fast at a temperature equal to or higher than a predetermined heating temperature, if the dopant gas is heated to the predetermined heating temperature or higher, the dopant gas is consumed in the gas supply chamber 2321 before the dopant is supplied to wafers 200, and thus it is difficult to control the amount of dopant supplied to the wafers 200. However, according to the present invention, since only the susceptors 218 and wafers 200 are heated, the dopant gas can be consumed mostly at the peripheries of the wafers 200, and thus the amount of dopant in films formed on the wafers 200 can be easily controlled.

(i) Since gas supplied through the gas supply holes 2322 located at sides of wafers 200 is discharged through the gas discharge holes 2312 located at the other sides of the wafers 200 after the gas makes contact with the wafers 200, the uniformity of films grown on the wafers 200 can be improved.

(j) Since wafers 200 are accommodated in the concave parts 218a of susceptors 218, slipping can be prevented at a temperature equal to higher than 1000° C.

### Second Embodiment

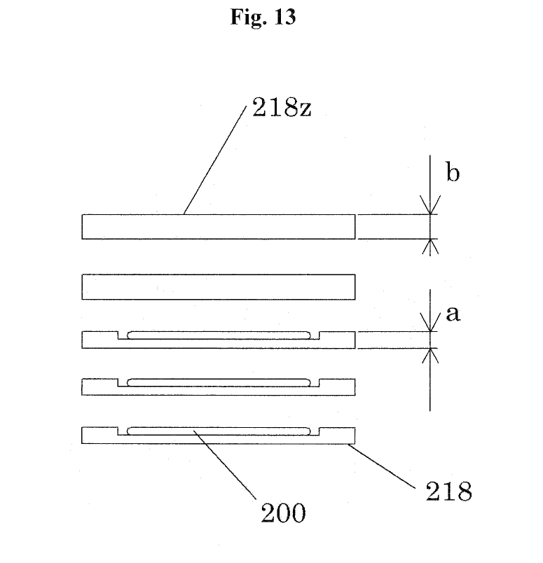

FIG. 13 is a side sectional view illustrating a state where dummy susceptors are provided at the upper side of a boat according to a second embodiment of the present invention. In FIG. 13, a boat 217 is not illustrated for conciseness.

With reference to FIG. 13, the second embodiment will now be briefly described. The second embodiment is the same as the first embodiment except for dummy susceptors 218z.

In the boat 217, heat is dissipated at the upper and lower sides, and thus the temperature conditions of the upper and lower sides are different from the temperature conditions of a wafer processing region, that is, the center part existing between the upper and lower sides for processing wafers 200. Therefore, according to the current embodiment, so as to improve the uniformity of a wafer heating region by controlling the upper and lower sides of the boat 217 with the same thermal history as the center part of the boat 217, the dummy susceptors 218z are disposed at the upper and lower sides of the boat 217 instead of disposing product wafers 200.

In addition, it is preferable that susceptors have different resistances. That is, the dummy susceptors 218z, which are disposed at the upper and lower sides where heat is easily dissipated, are configured to emit more heat, and susceptors disposed at the center part are configured to emit less heat. By this, a thermally uniform region can be increased in the vertical direction of the inside of the process chamber 201, and thus more wafers 200 can be batch-processed. For example, as shown in FIG. 13, the thickness (b) of the dummy susceptors 218z is adjusted to be greater than the thickness (a) of the susceptor 218 accommodating product wafers 200, so as to obtain different resistances. In addition, since the dummy susceptors 218z do not accommodate wafers 200, concave parts 218a are not formed in the dummy susceptors 218z, and thus the thickness of the dummy susceptors 218z can be increased by the depth of the concave parts 218a as compared with the of the susceptor 218 accommodating wafers 200, so as to increase the resistance of the dummy susceptors 218z.

### Third Embodiment

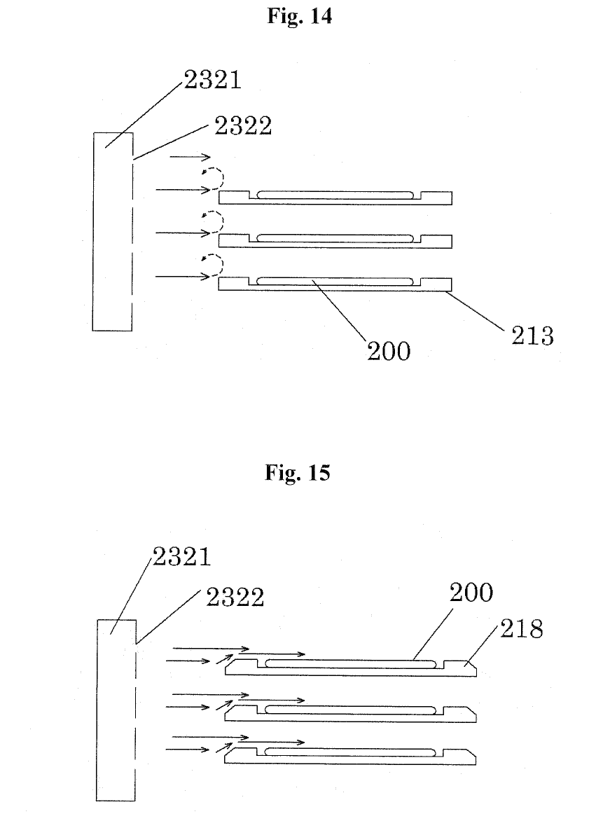

FIG. 14 is a side sectional view illustrating a state where a plurality of susceptors accommodated wafers in their concave parts are held by the boat according to the first embodiment of the present invention. FIG. 15 is a side sectional view illustrating an example where obtuse-angled parts are formed between the top and lateral peripheral surfaces of susceptors according to a third embodiment of the present invention. In the drawings, the boat 217 is not illustrated for conciseness.

With reference to FIG. 14 and FIG. 15, the third embodiment will now be described. The third embodiment is the same as the first embodiment except for the shape of the peripheries of the susceptors.

Since it takes considerable time to form thick films on wafers 200 at a vacuum pressure (1 Pa to 100 Pa), it is necessary to perform a film forming process on the wafers 200 at a pressure ranging from a low pressure (13300 Pa or higher) to atmospheric pressure. If a source gas is supplied to the wafers 200 under such a pressure, turbulent gas flows can be easily generated, which have bad influence on films growing on the wafers 200. Particularly, if turbulent flows are generated at positions close to the wafers 200 or at upstream sides, problems such as direct bad influence and degradation of in-surface film thickness uniformity are present. Susceptors 218 are located in the vicinities of the wafers 200 or at the upstream sides of the wafers 200, and due to angled parts between the top and lateral surfaces of the of the susceptors 218, turbulent gas flows can be generated as shown by arrows in FIG. 14.

Therefore, according to the current embodiment, preferably, as shown in FIG. 15, the parts between the top and lateral surfaces of the peripheral parts of the susceptors 218 are formed into an obtuse or round shape. Owning to this, as shown by arrows in FIG. 15, turbulent flows of a source gas can be reduced at the peripheries of the of the susceptors 218 which are located at the upstream side of the source gas supplied to wafers 200.

In addition, throughput can be improved by reducing the distance (pitch) between the susceptors 218 which are vertically arranged in multiple stages. However, if the distance (pitch) between the susceptors 218 vertically arranged in multiple stages is reduced, a wafer 200 supported on a susceptor 218 may be thermally affected by an upper susceptor 218 disposed just above the wafer 200, or the wafer 200 may be affected by turbulent gas flows caused by the angled periphery of the upper susceptor 218.

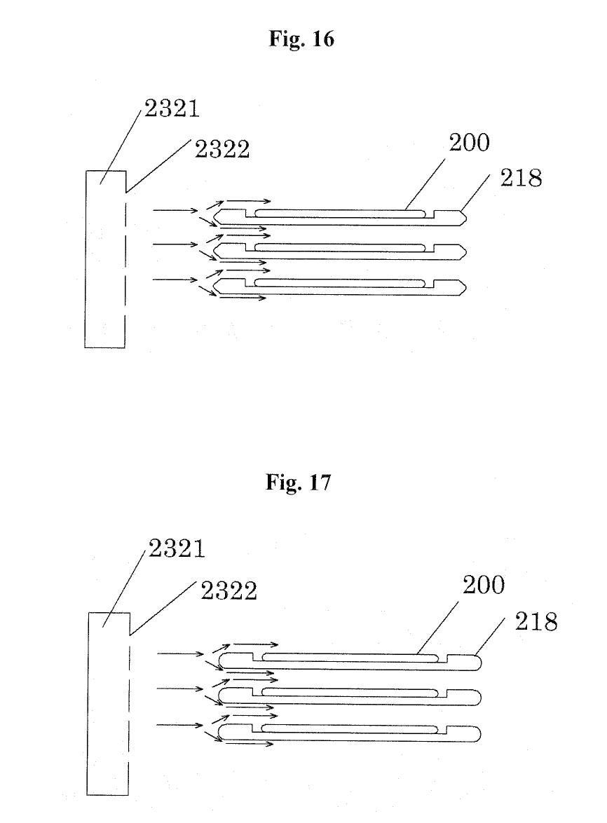

Therefore, preferably, as shown in FIG. 16, as well as the top and lateral surfaces of the peripheral parts of the susceptors 218, the bottom and lateral surfaces of the peripheral parts of the susceptors 218 are formed into an obtuse or round shape. Owing to this, as shown by arrows in FIG. 16, turbulent flows of a source gas can be reduced at the peripheries of the of the susceptors 218 which are located at the upstream side of the source gas supplied to wafers 200.

In addition, preferably, as shown in FIG. 17, the lateral surfaces of the peripheral parts of the susceptors 218 can be entirely rounded so as to further reduce turbulent flows of a source gas at the peripheries of the susceptors 218.

### Fourth Embodiment

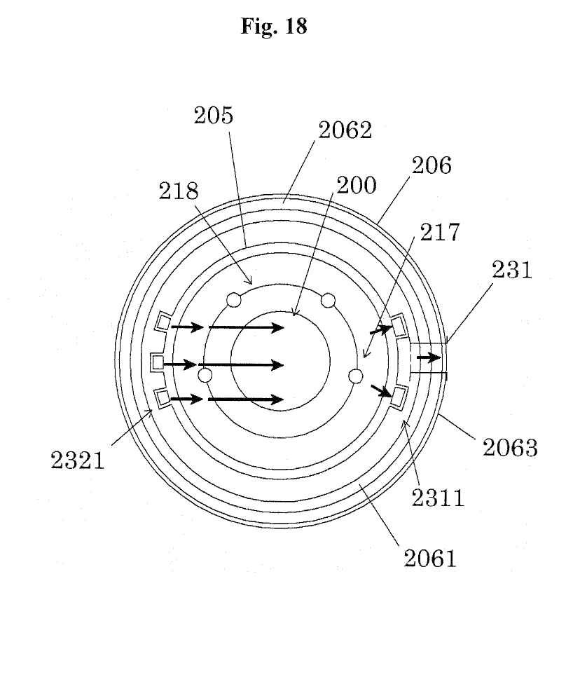

FIG. 18 is a horizontal sectional view illustrating a process furnace according to a fourth embodiment of the present invention.

With reference to FIG. 18, the fourth embodiment will now be described. The fourth embodiment is the same as the first embodiment except that a gas supply chamber 2321 and a gas exhaust chamber 2311 are provided at the lateral side of the outer wall of an outer tube 205.

When susceptors 218 are induction-heated, the outer tube 205, the gas supply chamber 2321, and the gas exhaust chamber 2311 are also heated to some degree due to causes such as thermal radiation and conduction from the susceptors 218. In this case, the outer tube 205, the gas supply chamber 2321, and the gas exhaust chamber 2311 can be cooled by controlling the blower 2065. However, since temperature increases as it goes close to the susceptors 218, if the gas supply chamber 2321 and the gas exhaust chamber 2311 are provided at the inner wall of the outer tube 205, the gas supply chamber 2321 and the gas exhaust chamber 2311 can be easily heated.

Particularly, if the temperature of the gas supply chamber 2321 increases, since gas consumption at the gas supply chamber 2321 increases, it becomes difficult to control the amount of process gas supplied to wafers 200 and the thickness of films. Furthermore, substances deposited on the gas supply chamber 2321 may be undesirably stripped and attached to the wafers 200, and the gas supply chamber 2321 or gas supply holes 2322 of the gas supply chamber 2321 may be clogged by the deposited substances.

For these reasons, according to the current embodiment, the gas supply chamber 2321 is provided at the lateral side of the outer wall of the outer tube 205. Owing to this structure, the distances from the susceptors 218 to the gas supply chamber 2321 and the gas supply holes 2322 can be increased, and thus the gas supply chamber 2321 and the gas supply holes 2322 can be less heated. Furthermore, preferably, the gas supply chamber 2321 may be installed on the lateral side of the outer wall of the outer tube 205 by welding. In this case, owing to thermal conduction to the outer tube 205 which is cooled, the gas supply chamber 2321 and the gas supply holes 2322 can be further cooled.

In addition, more preferably, a plurality of gas supply chambers 2321 may be provided. In this case, a film-forming gas can be supplied to the wafers 200 more uniformly. Much more preferably, it may be configured such that gas supply directions through the gas supply holes 2322 of the respective gas supply chambers 2321 are parallel with each other. In this case, the uniformity of film thickness on the wafers 200 can be improved much more.

In addition, it is preferably that the gas supply chambers 2321 be symmetric with respect to a center line of the wafers 200. In this case, gas can be supplied to the wafers 200 uniformly over the entire areas of the wafers 200.

Furthermore, it is preferable that the gas exhaust chamber 2311 be installed at the lateral side of the outer wall of the outer tube 205. In this case, the distances to the gas exhaust chamber 2311 and gas discharge holes 2312 of the gas exhaust chamber 2311 can be increased, and thus the gas exhaust chamber 2311 and the gas discharge holes 2312 can be less heated. Furthermore, preferably, the gas exhaust chamber 2311 may be installed at the outer wall of the outer tube 205 by welding. In this case, owing to thermal conduction to the outer tube 205 which is cooled, the gas exhaust chamber 2311 and the gas discharge holes 2312 can be further cooled.

In addition, more preferably, a plurality of gas exhaust chambers 2311 may be provided. In this case, a film-forming gas can be exhausted from the wafers 200 more uniformly. Much more preferably, it may be configured such that gas exhaust directions through the gas discharge holes 2312 of the respective gas exhaust chambers 2311 are parallel with each other. In this case, the uniformity of film thickness on the wafers 200 can be improved much more.

In addition, it is preferably that the gas exhaust chambers 2311 be symmetric with respect to a center line of the wafers 200. In this case, the entire process chamber 201 can be uniformly exhausted.

### Fifth Embodiment

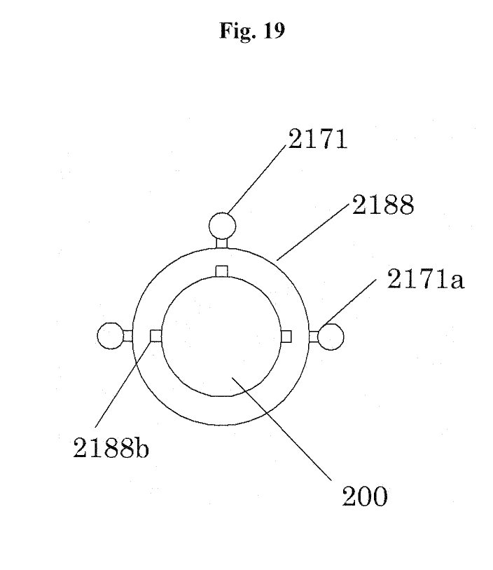

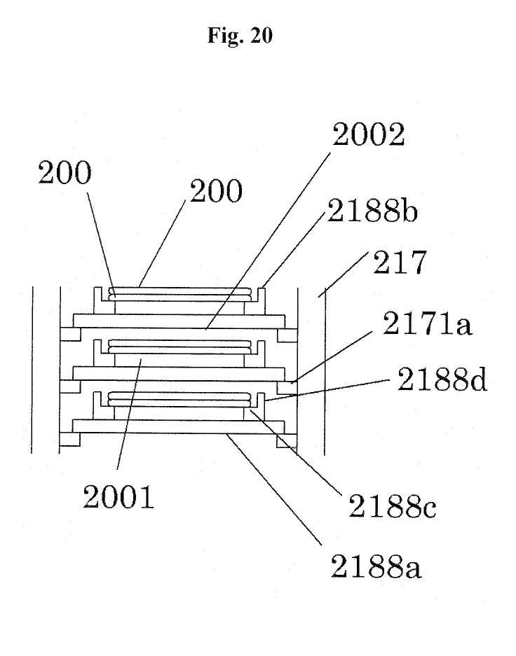

FIG. 19 is a horizontal sectional view illustrating a susceptor held at a boat according to a fifth embodiment of the present invention, and FIG. 20 is a side sectional view illustrating susceptors held at the boat according to the fifth embodiment of the present invention.

With reference to FIG. 19 and FIG. 20, the fifth embodiment will now be described. The fifth embodiment is the same as the first embodiment except for the shape of susceptors and the fact that a plurality of wafers 200 can be placed on each susceptor with the rear surfaces of the wafers 200 being in contact with each other.

First, the shape of susceptors 2188 will be described. Each of the susceptors 2188 includes a disk-shaped lower plate 2188a as a supporting plate, and supporting parts 2188b configured to support two wafers 200. The supporting parts 2188b are provided at at least three positions of the lower plate 2188a. Preferably, the three supporting parts 2188b are arranged along the circumference at regular intervals. In addition, it is also preferably that four or more supporting parts be provided. When two wafers 200 are held on the supporting parts 2188b of each susceptor 218, a first gap 2001 is formed between the lower plate 2188a and the lower wafer 200 of the two wafers 200, and the wafers 200 are horizontally held.

Each of the supporting parts 2188b includes a section 2188c configured to support a wafer 200 on its top surface, and a section 2188d configured to prevent a horizontal position difference of wafers 200. The section 2188d is higher than the section 2188c by at least the thickness of a wafer 200.

Owing to this, the positional difference of two wafers 200, which are placed on the top surfaces of the sections 2188c with the rear surfaces of the wafers 200 being in contact with each other, can be reduced. Preferably, the height of the section 2188d from the section 2188c corresponds to at least the thicknesses of two wafers 200. In this case, when two wafers 200 are placed on the sections 2188c, the top surfaces of the sections 2188d can be horizontally coplanar with the top surface of the upper wafer 200 of the two wafers 200, and thus the horizontal position difference of the two wafers 200 can be surely prevented and gas can flow smoothly along the top surface of the upper wafer 200.

In a state where the rear surfaces of two wafers 200 make contact with each other, the two wafers 200 are supported by the susceptor 2188. Susceptors 2188 each accommodating two wafers 200 are held by the boat 217 in multiple stages. In the state where the susceptors 2188 are held by the boat 217, a second gap 2002 is formed between the upper wafer 200 of the two wafers 200 accommodated in one susceptor 2188 and the bottom surface of the just upper susceptor 2188.

Owing to this structure, for the top surface, that is, the front surface, of the upper wafer 200 of two wafers 200 accommodated in the susceptor 2188, the second gap 2002 becomes a film-forming gas passage so that a desired film can be formed on the top surface of the upper wafer 200. In addition, for the bottom surface, that is, the front surface, of the lower wafer 200 of the two wafers 200 accommodated in the susceptor 2188, the first gap becomes a film-forming gas passage so that a desired film can be formed on the bottom surface of the lower wafer 200. At this time, since the rear surfaces of the two wafers 200 are in contact with each other, growth of films on the rear surfaces can be prevented. Furthermore, since the positional difference of the two wafers 200 is prevented by the sections 2188d of the supporting parts 2188b, growth of films on the rear surfaces of the two wafers 200 can be prevented more surely.

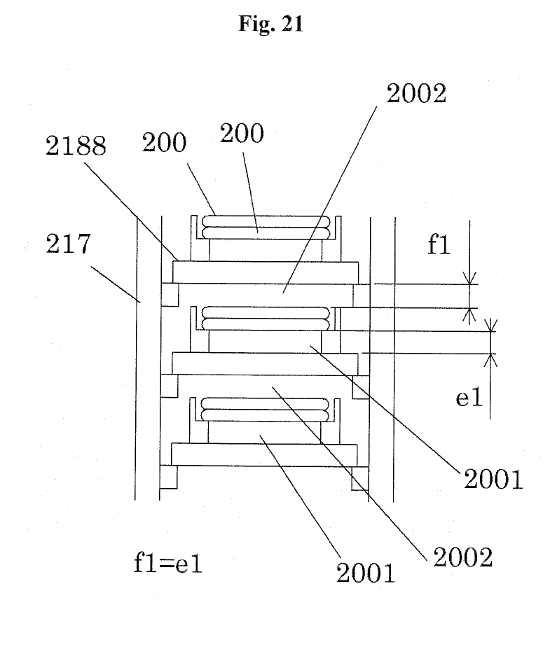

Preferably, as shown in FIG. 21, for heating gas flowing through the second gap 2002, the upper wafer 200, gas flowing through the first gap 2001, and the lower wafer 200 by using the susceptors 2188, and forming films the same thickness and quality on the upper and lower wafers 200, the holding parts 2171 a of the boat 217 may be arranged in a manner such that the distance f1 between the upper susceptor 2188 of the second gap 2002 and the upper wafer 200 supported by the lower susceptor of the second gap 2002 can be equal to the distance e1 between the lower wafer 200 supported by the lower susceptor 2188 of the first gap 2001 and the lower susceptor 2188 of the first gap 2001.

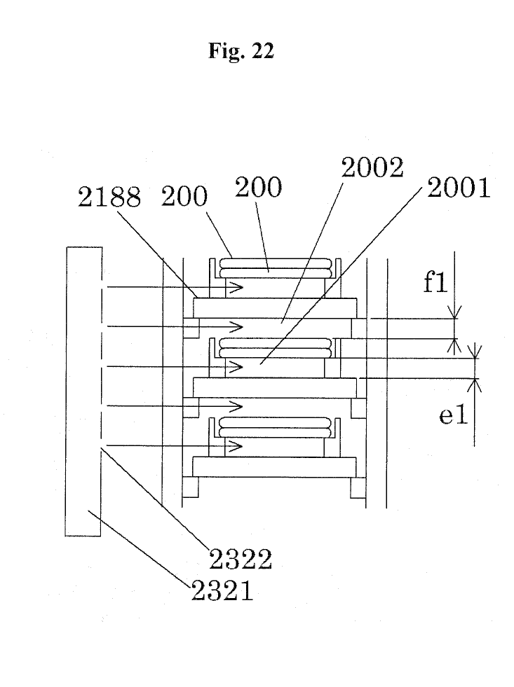

In addition, preferably, as shown in FIG. 22, so as to supply gas to the first and second gaps 2001 and 2002 more uniformly, gas supply holes 2322 of a gas supply chamber 2321 may be configured to face the first and second gaps 2001 and 2002, respectively, in a manner such that a first gas supply hole faces the first gap 2001 and a second gas supply hole faces the second gap 2002.

In addition, since the direct contact area between the lower wafer 200 and the sections 2188c of the supporting parts 2188b of the susceptor 2188 is large, the lower wafer 200 may not be uniformly heated.

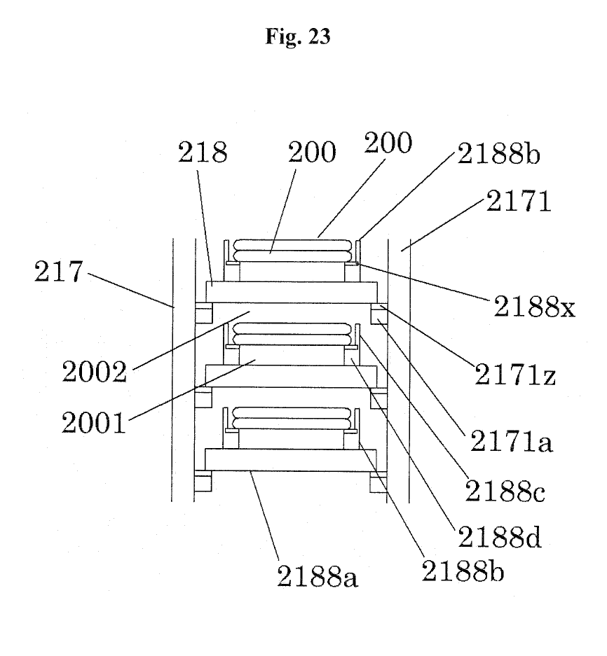

For that case, it is preferable that heat conduction reducing materials 2188x having a thermal conductivity lower than that of the susceptor 2188 be provided on at least portions of the sections 2188c that make contact with the lower wafer 200 as shown in FIG. 23. The heat conduction reducing materials 2188x may be sintered silicon nitride.

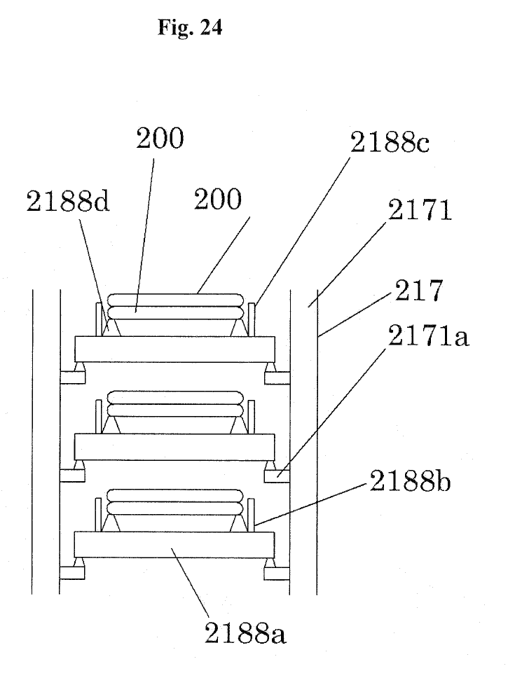

In addition, preferably, as shown in FIG. 24, so as to reduce the contact areas between the holding parts 2171a and the lower plate 2188a while maintaining the strength of the holding parts 2171a, the holding parts 2171a may have a prismatic or cylindrical parts having a trapezoidal section with a top side shorter than a bottom side. In this case, if the boat 217 is made of a material that is thermally degraded at temperatures lower than a wafer processing temperature, it is preferable that heat conduction reducing materials be provided on at least contact surfaces with the susceptors 218 as described above.

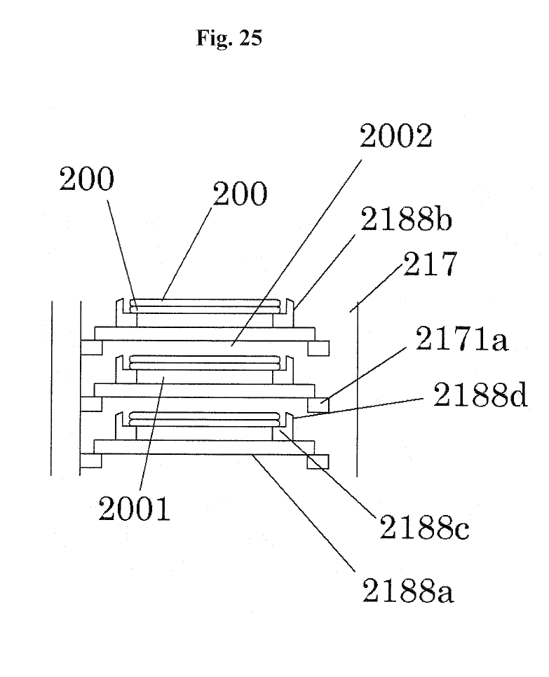

In addition, preferably, as shown in FIG. 25, obtuse-angled or rounded parts may be formed between the top and lateral surfaces of the sections 2188d.

More preferably, as well as the top and lateral surfaces of the sections 2188d, the top and lateral surfaces of the lower plates 2188a may be obtuse-angled or rounded. Much more preferably, as well as the top and lateral surfaces of the sections 2188d, the top and lateral surfaces of the lower plates 2188a may be obtuse-angled or rounded and the bottom and lateral surfaces of the lower plates 2188a may be obtuse-angled or rounded.

In addition, preferably, the entire lateral surfaces of the lower plates 2188a may be rounded.

In addition, the boat 217 is configured such that each set of the holding parts 2171a holds one susceptor 218 and each susceptor 218 accommodates two wafer 200 with the rear surfaces of the two wafers 200 being in contact with each other, and in this way, fifty to one hundred susceptors 218 and the corresponding number of wafers 200 can be charged into the boat 217.

### Sixth Embodiment

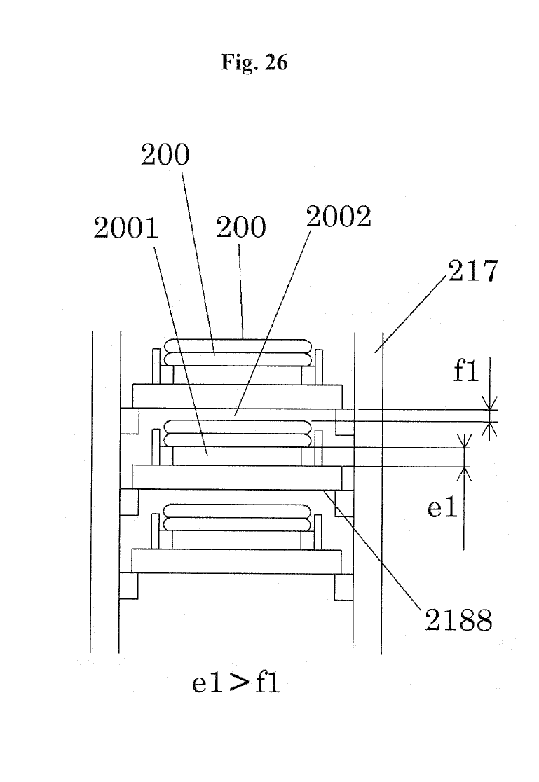

FIG. 26 is a side sectional view illustrating a state where the distance from the lower wafer of two wafers supported by a first susceptor held at the boat to the first susceptor is greater than the distance from a neighboring second susceptor to the upper wafer of the two wafers according to a sixth embodiment of the present invention.

With reference to FIG. 26, the sixth embodiment will now be described. The sixth embodiment is the same as the fifth embodiment except that the distance between neighboring upper and lower susceptors is changed. In the above-described fifth embodiment, due to the supporting parts 2188b of the susceptors 2188, a gas flow through the first gap 2001 may be hindered in some degree, and thus the thickness of a film formed on the lower wafer 200 of two wafers 200 accommodated on the lower susceptor 2188 may be smaller than the thickness of a film formed on the upper wafer 200 of the two wafers 200.

Therefore, in the current embodiment, holding parts 2171a of a boat 217 is arranged in a manner such that the distance e1 from the lower wafer 200 supported by the lower susceptor 2188 of a first gap 2001 to the lower susceptor 2188 is greater than the distance f1 from the upper susceptor 2188 of a second gap 2002 to the upper wafer 200 supported by the lower susceptor 2188. In this case, films having the same thickness and quality can be formed on the upper and lower wafers 200 more reliably.

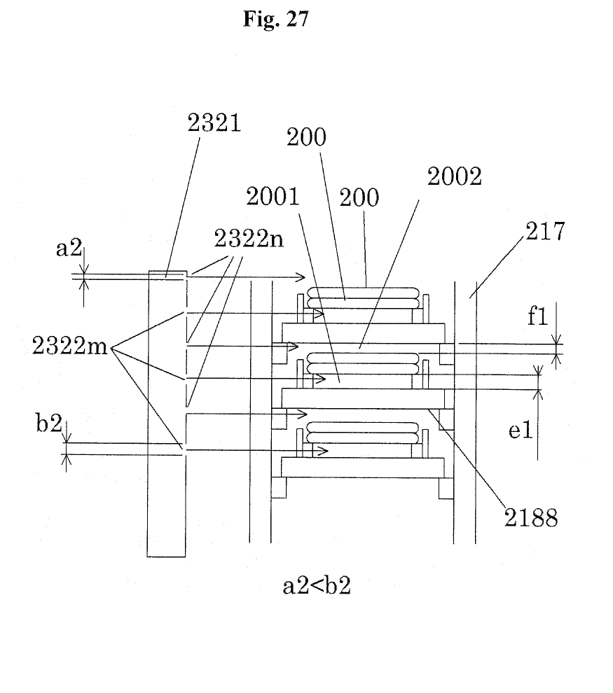

In addition, preferably, so as to supply more gas to first gaps 2001 than second gaps 2002, as shown in FIG. 27, gas supply holes 2322 of a gas supply chamber 2321 may be configured to face the first and second gaps 2001 and 2002, respectively, in a manner such that the size of third gas supply holes 2322m configured to supply gas to the first gaps 2001 is greater than the size of fourth gas supply holes 2322n configured to supply gas to the second gap 2002.

### Other Embodiments

While the present invention has been described with reference to embodiments, the present invention is not limited thereto. The semiconductor film forming conditions described in the embodiments are exemplary conditions, and variations or modifications are possible. For example, when an epitaxial layer is formed by growing a silicon single crystal film, Si-based gas and SiGe-based gas such as SiH₄, Si₂H₆, SiH₂Cl₂, SiHCl₃, and SiCl₄ can be used as a source gas. Furthermore, an epitaxial layer can be formed by growing a compound semiconductor layer on a substrate such as a GaAs substrate. In addition, gas such as B₂H₆, BCl₃, a_{nd} PH₃ can be used as a doping gas.

Gas supply methods have been explained for the exemplary case where the gas supply chamber and the gas exhaust chamber are provided in the outer tube; however, if thermal conduction between the outer tube and the gas supply chamber and between the outer tube and the gas exhaust chamber is not significantly necessary, instead of the gas supply chamber, a plurality of gas supply nozzles which are separate from and independent of the outer tube may be erected in the outer tube. In addition, a plurality of gas supply holes may be formed through the sidewalls of the gas supply nozzles. Furthermore, instead of the gas exhaust chamber, a plurality of gas exhaust nozzles which are separate from and independent of the outer tube may be erected in the outer tube. In addition, a plurality of gas discharge holes may be formed through the sidewalls of the gas exhaust nozzles. Furthermore, instead of installing the gas exhaust chamber, the inside of the process chamber may be exhausted directly through the gas exhaust pipe.

In the above-described embodiments, the loadlock chamber that can be vacuum-evacuated is exemplarily described as a standby chamber; however, in the case of performing a process in which attachment of a natural oxide layer to a substrate does not cause significant problem, instead of using the loadlock chamber that can be vacuum-evacuated, a cleaning method not using vacuum evacuation but using nitrogen gas or clean air atmosphere may be employed. In this case, a simple case may be used instead of a pressure-resistant case.

As a susceptor holding mechanism, as shown in FIG. 4 to FIG. 6, the pin holes formed in the susceptor 218, the push pins inserted in the pin holes, and the push pin elevating mechanism have been described. However, the present invention is not limited thereto. For example, instead of using the pin holes, the push pins, and the push pin elevating mechanism, the tweezers may be used for charging a wafer 200 to a susceptor and discharging the wafer 200 from the susceptor, in a manner such that the tweezers holds the wafer 200 by sucking a top surface region of the wafer 200 that does not affect the film forming characteristics of the top surface of the wafer 200.

In addition, the present invention has been described by taking a CVD apparatus as an example; however, the present invention can be applied to other substrate processing apparatuses such as an epitaxial growing apparatus, an atomic layer deposition (ALD) apparatus, an oxidation apparatus, a diffusion apparatus, and an annealing apparatus.

The second embodiment can be applied to the third to sixth embodiments, and the third embodiment can be applied to the fourth embodiment. In addition, the fourth embodiment can be applied to the fifth and sixth embodiments.

In addition, in the above-described embodiments, it has been explained that after a substrate processing process, a process for removing substances attached to the rear surface of a wafer can be omitted. However, if necessary, after a substrate processing process, such a process may be performed to remove a small amount of substances attached to the rear surface of a wafer. Furthermore, if necessary, in another process after a substrate processing process, substances attached to the rear surface of a wafer may be removed.

As described above, the present invention provides a substrate processing apparatus and a method of manufacturing a semiconductor device, which are designed to form desired films on the front surfaces of a plurality of substrates through a batch process while preventing formation of films on the rear surfaces of the substrates.

The present invention also includes at least the following embodiments.

(Supplementary Note 1)

According to a preferred embodiment of the present invention, there is provided a substrate processing apparatus comprising:

a reaction vessel configured to process substrates therein;

supports made of a conductive material and having a plate shape, each of the supports being configured to accommodate a substrate in a concave part of the support in a state where the substrate is horizontally positioned with a front surface of the substrate being exposed;

a support holder configured to hold at least the supports horizontally in multiple stages; and

an induction heating device configured to heat at least the supports held by the support holder inside the reaction vessel by using an induction heating method.

(Supplementary Note 2)

In the substrate processing apparatus of Supplementary Note 1, the support may have a disk shape, the concave part may be formed concentrically with a circumference of the support, and a difference between radii of the support and the concave part may be greater than a distance between neighboring two of the supports held by the support holder.

(Supplementary Note 3)

In the substrate processing apparatus of Supplementary Note 1, the concave part may have a depth equal to the thickness of the substrate.

(Supplementary Note 4)

The substrate processing apparatus of Supplementary Note 1, may further comprise a gas supply unit configured to supply gas in a direct from a lateral side of the support to the substrate accommodated in the concave part of the support, and wherein top and lateral surfaces of the support may be obtuse-angled or rounded over the entire circumference of the support.

(Supplementary Note 5)

In the substrate processing apparatus of Supplementary Note 4, bottom and lateral surfaces of the support may be obtuse-angled or rounded over the entire circumference of the support.

(Supplementary Note 6)

In the substrate processing apparatus of Supplementary Note 1, the support holder may comprise a holding part configured to hold the support, and a heat conduction reducing material may be provided on at least a surface of the holding part that makes contact with the support.

(Supplementary Note 7)

In the substrate processing apparatus of Supplementary Note 1, the support holder may be made of a material having a thermal conductivity lower than that of the support.

(Supplementary Note 8)

In the substrate processing apparatus of Supplementary Note 1, the support holder may be made of a material having a resistance higher than that of the support.

(Supplementary Note 9)

According to another preferred embodiment of the present invention, there is provided a substrate processing apparatus comprising:

a reaction vessel configured to process substrates therein;

a first support made of a conductive material and comprising a first supporting part and a first plate on which the first supporting part is installed, the first supporting part being configured to support first and second substrates horizontally with rear surfaces of the first and second substrates being in contact with each other, the first plate being configured to form a first gap with the second substrate supported by the first supporting part;

a second support made of a conductive material and disposed close to a top side of the first support;

a support holder configured to hold the first support on a first support holding part and the second support on a second support holding part in a manner such that the first and second supports are horizontally positioned and arranged in multiple stages with a second gap being formed between the first and second supports, wherein the first support holding part and the second support holding part of the support holder are arranged such that a first distance in the first gap between the first support and the second substrate is equal to or greater than a second distance defined in the second gap between the second support and the first substrate; and

an induction heating device configured to heat at least the first and second supports which are respectively held on the first and second support holding parts of the support holder inside the reaction vessel.

(Supplementary Note 10)

In the substrate processing apparatus of Supplementary Note 9, the first supporting part may comprise a grooved section having a depth greater than at least a thickness of the second substrate.

(Supplementary Note 11)

The substrate processing apparatus of Supplementary Note 9, may further comprise a gas supply unit which is installed in the reaction vessel and comprises a plurality of gas supply holes, wherein the gas supply holes may comprise at least a first gas supply hole through which gas is supplied to the first gap and a second gas supply hole through which gas is supplied to the second gap.

(Supplementary Note 12)

In the substrate processing apparatus of Supplementary Note 11, the first gas supply hole may have a size greater than that of the second gas supply hole.

(Supplementary Note 13)

In the substrate processing apparatus of Supplementary Note 9, a heat conduction reducing material having a low thermal conductivity may be provided on at least a section of the first supporting part that makes contact with the second substrate.

(Supplementary Note 14)

According to another preferred embodiment of the present invention, there is provided a substrate processing apparatus comprising:

a reaction vessel configured to process substrates therein;

a first support made of a conductive material and comprising a first supporting part and a first plate on which the first supporting part is installed, the first supporting part being configured to support first and second substrates horizontally with rear surfaces of the first and second substrates being in contact with each other, the first plate being configured to form a first gap with the second substrate supported by the first supporting part;

a second support made of a conductive material and disposed close to a top side of the first support;

a support holder configured to hold the first support on a first support holding part and the second support on a second support holding part in a manner such that the first and second supports are horizontally positioned and arranged in multiple stages with a second gap being formed between the first and second supports; and

an induction heating device configured to heat at least the first and second supports which are respectively held on the first and second support holding parts of the support holder inside the reaction vessel.

(Supplementary Note 15)

According to another preferred embodiment of the present invention, there is provided a method of manufacturing a semiconductor device by processing a substrate, the method comprising:

loading a support holder into a reaction vessel, wherein the support holder holds a plurality of supports horizontally in multiple stages, each of the supports is made of a conductive material and has a plate shape, and each of the supports accommodates a substrate in a concave part of the support in a state where the substrate is horizontally positioned with a top surface of the substrate being exposed; and

processing the substrates by heating the supports using an induction heating device.

(Supplementary Note 16)

In the method of Supplementary Note 15, bottom and lateral surfaces of the supports may be obtuse-angled or rounded, and in the processing of the substrates, gas may be supplied from lateral sides of the supports to the substrates accommodated in the concave parts of the supports.

(Supplementary Note 17)

According to another preferred embodiment of the present invention, there is provided a method of manufacturing a semiconductor device, the method comprising:

supporting first and second substrates horizontally by using a first support which is made of a conductive material and comprises a first supporting part and a first plate on which the first supporting part is installed, wherein the first and second substrates are supported on the first support in a state where rear surfaces of the first and second substrates are in contact with each other and a first gap is formed between the second substrate and the first plate;

supporting third and fourth substrates horizontally by using a second support which is made of a conductive material and comprises a second supporting part and a second plate on which the second supporting part is installed, wherein the third and fourth substrates are supported on the second support in a state where rear surfaces of the third and fourth substrates are in contact with each other and a second gap is formed between the fourth substrate and the second plate;

carrying the first support on which the first and second substrate are supported and the second support on which the third and fourth substrate are supported, so as to hold the first and second supports by using a support holder in a state where a first distance in the first gap between the first support and the second substrate is equal to or greater than a second distance between the second support and the first substrate; and

after loading the support holder, which holds the first support on which the first and second substrates are supported and the second support on which the third and fourth substrates are supported, into a reaction vessel, heating the first and second supports by using an induction heating device so as to process the first to fourth substrates.

What is claimed is:

1. A substrate processing apparatus comprising:
a reaction vessel configured to process substrates therein;
supports made of a conductive material and having a disk shape, each of the supports being configured to accommodate a substrate in a concave part of the support in a state where the substrate is horizontally positioned with a top surface of the substrate being exposed;
a support holder configured to hold at least the supports horizontally in multiple stages; and
an induction heating device configured to heat at least the supports held by the support holder inside the reaction vessel by using an induction heating method,
wherein the concave part is formed concentrically with a circumference of the support, and
a difference between radii of the support and the concave part is greater than a distance between neighboring two of the supports held by the support holder.

2. The substrate processing apparatus of claim 1, further comprising a gas supply unit configured to supply gas in a direct from a lateral side of the support to the substrate accommodated in the concave part of the support,
wherein top and lateral surfaces of the support are obtuse-angled or rounded over the entire circumference of the support.

3. The substrate processing apparatus of claim 2, wherein bottom and lateral surfaces of the support are obtuse-angled or rounded over the entire circumference of the support.

4. The substrate processing apparatus of claim 1, wherein the support holder comprises a holding part configured to hold the support, and a heat conduction reducing material is provided on at least a surface of the holding part that makes contact with the support.

5. A substrate processing apparatus comprising:
a reaction vessel configured to process substrates therein;
a first support made of a conductive material and comprising a first supporting part and a first plate on which the first supporting part is installed, the first supporting part being configured to support first and second substrates horizontally with rear surfaces of the first and second substrates being in contact with each other, the first plate being configured to form a first gap with the second substrate supported by the first supporting part;
a second support made of a conductive material and disposed close to a top side of the first support;
a support holder configured to hold the first support on a first support holding part and the second support on a second support holding part in a manner such that the first and second supports are horizontally positioned and arranged in multiple stages with a second gap being formed between the first and second supports; and
an induction heating device configured to heat at least the first and second supports which are respectively held on the first and second support holding parts of the support holder inside the reaction vessel.

6. The substrate processing apparatus of claim 5, wherein the first support holding part and the second support holding part of the support holder are arranged such that a first distance in the first gap between the first support and the second substrate is equal to or greater than a second distance defined in the second gap between the second support and the first substrate.

7. The substrate processing apparatus of claim 5, wherein the first supporting part comprises a grooved section having a depth greater than at least a thickness of the second substrate.

8. The substrate processing apparatus of claim 5, further comprising a gas supply unit which is installed in the reaction vessel and comprises a plurality of gas supply holes,
wherein the gas supply holes comprise at least a first gas supply hole through which gas is supplied to the first gap and a second gas supply hole through which gas is supplied to the second gap.

9. The substrate processing apparatus of claim 8, wherein the first gas supply hole has a size greater than that of the second gas supply hole.

10. The substrate processing apparatus of claim 5, wherein a heat conduction reducing material is provided on at least a section of the first supporting part that makes contact with the second substrate.
